(19) United States
(12) Patent Application Publication
(10) Pub. No.: US 2025/0056855 A1
(43) Pub. Date: Feb. 13, 2025

(54) SEMICONDUCTOR DEVICE AND METHOD OF MAKING

(71) Applicant: Taiwan Semiconductor Manufacturing Company Limited, Hsin-Chu (TW)

(72) Inventors: Zhuo-Cang YANG, Hsinchu City (TW); June-Sheng TSAI, Hsinchu County (TW); Pin Yu HSU, Hsinchu County (TW); Kuo-Lung TZENG, Yilan County (TW); Hsin-Chi CHEN, Tainan City (TW)

(21) Appl. No.: 18/440,331

(22) Filed: Feb. 13, 2024

Related U.S. Application Data
(60) Provisional application No. 63/531,383, filed on Aug. 8, 2023.

(51) Int. Cl. H01L 29/36; H01L 21/265; H01L 29/78

(52) U.S. Cl. CPC H01L 29/36; H01L 21/2652; H01L 29/78

(57) ABSTRACT

A semiconductor device is provided. The semiconductor device includes a semiconductor body and a transistor. The transistor includes a drain region in the semiconductor body, a first doped region in the drain region, a source region in the semiconductor body, a second doped region adjacent the source region, and a third doped region between the first doped region and the second doped region. The third doped region includes a first portion having a first concentration of dopants, a second portion adjacent the first portion and having a second concentration of dopants, a third portion adjacent the second portion and having a third concentration of dopants, and a fourth portion adjacent the third portion and having a fourth concentration of dopants. The first concentration is less than the second concentration. The second concentration is greater than the third concentration. The third concentration is less than the fourth concentration.

### CROSS-REFERENCE TO RELATED APPLICATIONS

This application claims priority to U.S. provisional application 63/531,383, titled “Semiconductor Device Having Reduced Device Size or ON Resistance” and filed on Aug. 8, 2023, which is incorporated herein by reference.

### BACKGROUND

Semiconductor devices are used in a multitude of electronic devices, such as mobile phones, laptops, desktops, tablets, watches, gaming systems, and various other industrial, commercial, and consumer electronics. Semiconductor devices generally comprise semiconductor portions and wiring portions formed inside the semiconductor portions.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1B illustrate a semiconductor device at a stage of fabrication, in accordance with some embodiments.

FIGS. 2A-2B illustrate a semiconductor device at a stage of fabrication, in accordance with some embodiments.

FIGS. 3A-3B illustrate a semiconductor device at a stage of fabrication, in accordance with some embodiments.

FIGS. 4A-4C illustrate a semiconductor device at a stage of fabrication, in accordance with some embodiments.

FIGS. 5A-5C illustrate a semiconductor device at a stage of fabrication, in accordance with some embodiments.

FIGS. 6A-6B illustrate a semiconductor device at a stage of fabrication, in accordance with some embodiments.

FIGS. 7A-7B illustrate a semiconductor device at a stage of fabrication, in accordance with some embodiments.

FIGS. 8A-8E illustrate a semiconductor device at a stage of fabrication, in accordance with some embodiments.

FIG. 8F illustrates a dopant concentration data structure comprising a curve indicative of concentrations of dopants along a line, in accordance with some embodiments.

FIG. 9 illustrates a semiconductor device, in accordance with some embodiments.

FIG. 10 illustrates a semiconductor device, in accordance with some embodiments.

FIG. 11 illustrates a semiconductor device, in accordance with some embodiments.

FIG. 12 illustrates a semiconductor device, in accordance with some embodiments.

FIG. 13A illustrates a semiconductor device, in accordance with some embodiments.

FIG. 13B illustrates a dopant concentration data structure comprising a curve indicative of concentrations of dopants along a line, in accordance with some embodiments.

FIG. 14A illustrates a semiconductor device, in accordance with some embodiments.

FIG. 14B illustrates a dopant concentration data structure comprising a curve indicative of concentrations of dopants along a line, in accordance with some embodiments.

FIG. 15A illustrates a semiconductor device, in accordance with some embodiments.

FIG. 15B illustrates a dopant concentration data structure comprising a curve indicative of concentrations of dopants along a line, in accordance with some embodiments.

FIG. 16A illustrates a semiconductor device, in accordance with some embodiments.

FIG. 16B illustrates a dopant concentration data structure comprising a curve indicative of concentrations of dopants along a line, in accordance with some embodiments.

FIG. 17A illustrates a semiconductor device, in accordance with some embodiments.

FIG. 17B illustrates a dopant concentration data structure comprising a curve indicative of concentrations of dopants along a line, in accordance with some embodiments.

FIG. 18A illustrates a semiconductor device, in accordance with some embodiments.

FIG. 18B illustrates a dopant concentration data structure comprising a curve indicative of concentrations of dopants along a line, in accordance with some embodiments.

FIG. 19 illustrates a semiconductor device, in accordance with some embodiments.

FIG. 20 illustrates a semiconductor device, in accordance with some embodiments.

FIG. 21 illustrates a semiconductor device, in accordance with some embodiments.

FIG. 22A illustrates a semiconductor device, in accordance with some embodiments.

FIG. 22B illustrates a dopant concentration data structure comprising a curve indicative of concentrations of dopants along a line, in accordance with some embodiments.

FIG. 23A illustrates a semiconductor device, in accordance with some embodiments.

FIG. 23B illustrates a dopant concentration data structure comprising a curve indicative of concentrations of dopants along a line, in accordance with some embodiments.

FIG. 24A illustrates a semiconductor device, in accordance with some embodiments.

FIG. 24B illustrates a dopant concentration data structure comprising a curve indicative of concentrations of dopants along a line, in accordance with some embodiments.

FIG. 25A illustrates a semiconductor device, in accordance with some embodiments.

FIG. 25B illustrates a dopant concentration data structure comprising a curve indicative of concentrations of dopants along a line, in accordance with some embodiments.

FIG. 26A illustrates a semiconductor device, in accordance with some embodiments.

FIG. 26B illustrates a dopant concentration data structure comprising a curve indicative of concentrations of dopants along a line, in accordance with some embodiments.

FIG. 27A illustrates a semiconductor device, in accordance with some embodiments.

FIG. 27B illustrates a dopant concentration data structure comprising a curve indicative of concentrations of dopants along a line, in accordance with some embodiments.

FIG. 28A illustrates a semiconductor device, in accordance with some embodiments.

FIG. 28B illustrates a dopant concentration data structure comprising a curve indicative of concentrations of dopants along a line, in accordance with some embodiments.

FIG. 29A illustrates a semiconductor device, in accordance with some embodiments.

FIG. 29B illustrates a dopant concentration data structure comprising a curve indicative of concentrations of dopants along a line, in accordance with some embodiments.

FIGS. 30A-30D illustrate a semiconductor device, in accordance with some embodiments.

FIGS. 31A-31B illustrate a semiconductor device, in accordance with some embodiments.

### DETAILED DESCRIPTION

The following disclosure provides several different embodiments, or examples, for implementing different features of the provided subject matter.

Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples.

This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

The term “overlying” and/or the like may be used to describe one element or feature being vertically coincident with and at a higher elevation than another element or feature. For example, a first element overlies a second element if the first element is at a higher elevation than the second element and at least a portion of the first element is vertically coincident with at least a portion of the second element.

The term “underlying” and/or the like may be used to describe one element or feature being vertically coincident with and at a lower elevation than another element or feature. For example, a first element underlies a second element if the first element is at a lower elevation than the second element and at least a portion of the first element is vertically coincident with at least a portion of the second element.

The term “over” may be used to describe one element or feature being at a higher elevation than another element or feature. For example, a first element is over a second element if the first element is at a higher elevation than the second element.

The term “under” may be used to describe one element or feature being at a lower elevation than another element or feature. For example, a first element is under a second element if the first element is at a lower elevation than the second element.

In the present disclosure, source/drain region(s) may refer to a source or a drain, individually or collectively dependent upon the context.

A semiconductor device has a semiconductor body and a transistor comprising a drain region in the semiconductor body, a first doped region in the drain region, a source region in the semiconductor body, a second doped region adjacent the source region, and a third doped region between the first doped region and the second doped region. In some embodiments, the third doped region comprises a diffused third doped region. In some embodiments, the third doped region is formed via at least one of (i) implanting dopants into locales of the semiconductor body to form portions of a doped region, or (ii) performing an anneal on the semiconductor body. In some embodiments, the locales are spaced apart from each other such that a first portion of the doped region is separated from a second portion of the doped region by a portion of the semiconductor body. In some embodiments, one or more anneals causes diffusion of dopants of the doped region to form the third doped region. In some embodiments, the third doped region has a gradient such that a concentration of dopants changes along a line through the third doped region. In some embodiments, the third doped region has a sidewall that is non-linear such that a first portion of the sidewall is separated from a second portion of the sidewall by a portion of the semiconductor body. In some embodiments, at least one of the third doped region having the gradient or the sidewall of the third doped region being non-linear provides for at least one of a reduction of an on state resistance (Ron) of the transistor, or a reduction of at least one of a device size of the semiconductor device, a transistor size of the transistor, a transistor pitch, etc. In some embodiments, reducing the on state resistance of the transistor provides for reduced power consumption of the transistor, and thus improved operating efficiency. Given the reduced power consumption, the semiconductor device operates more efficiently than other devices.

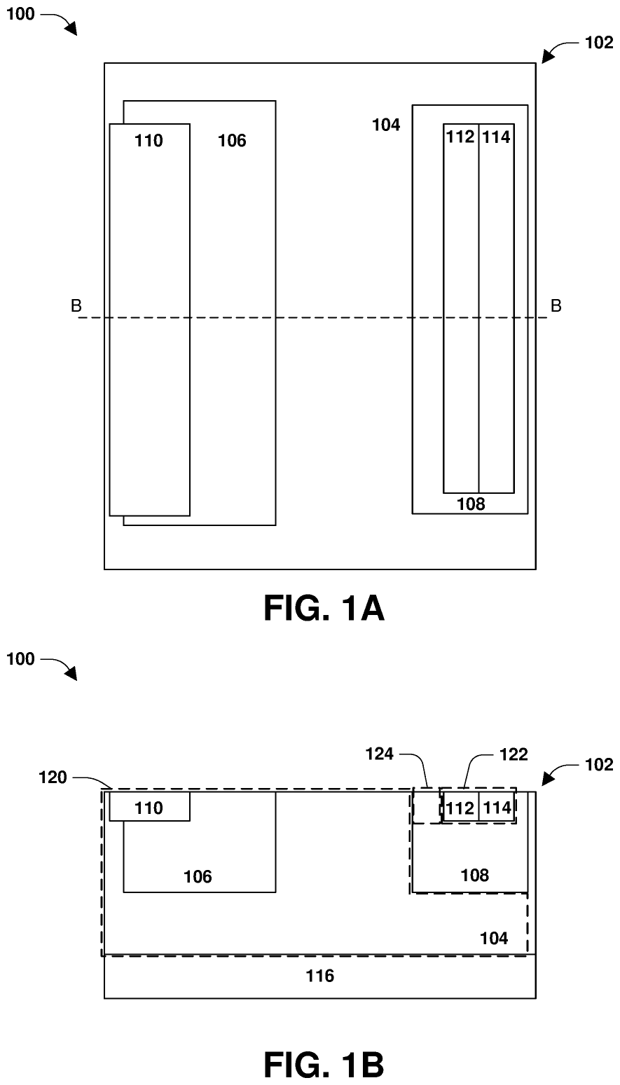

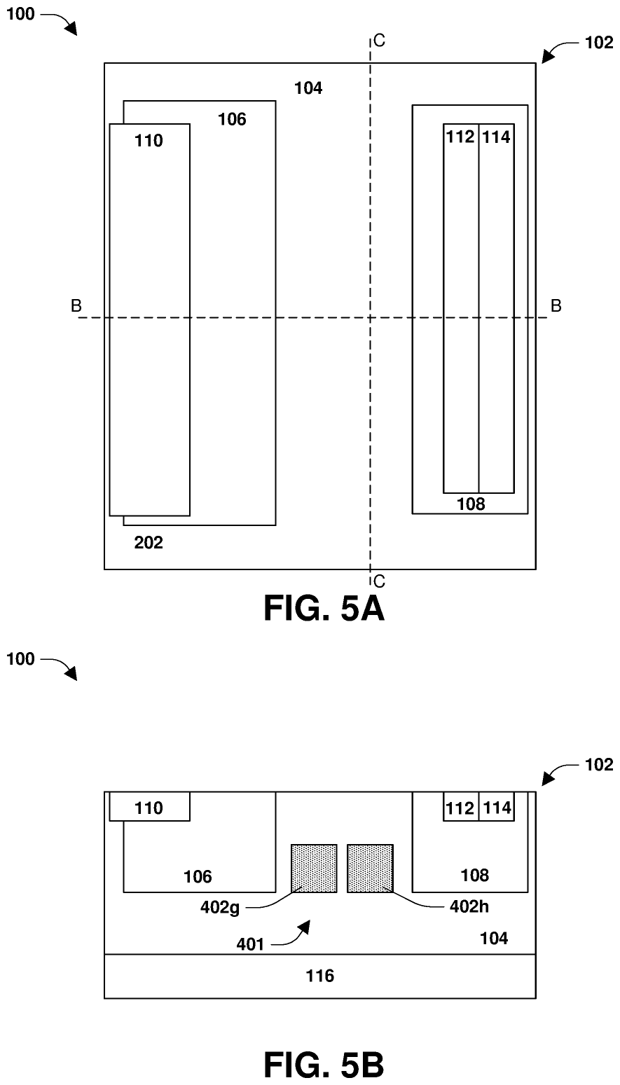

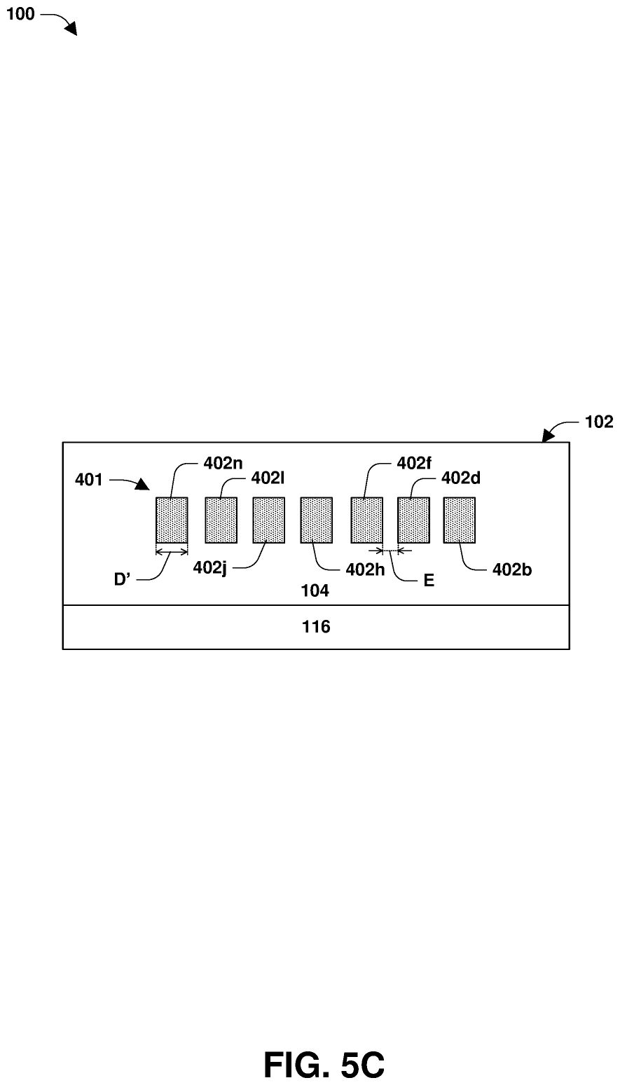

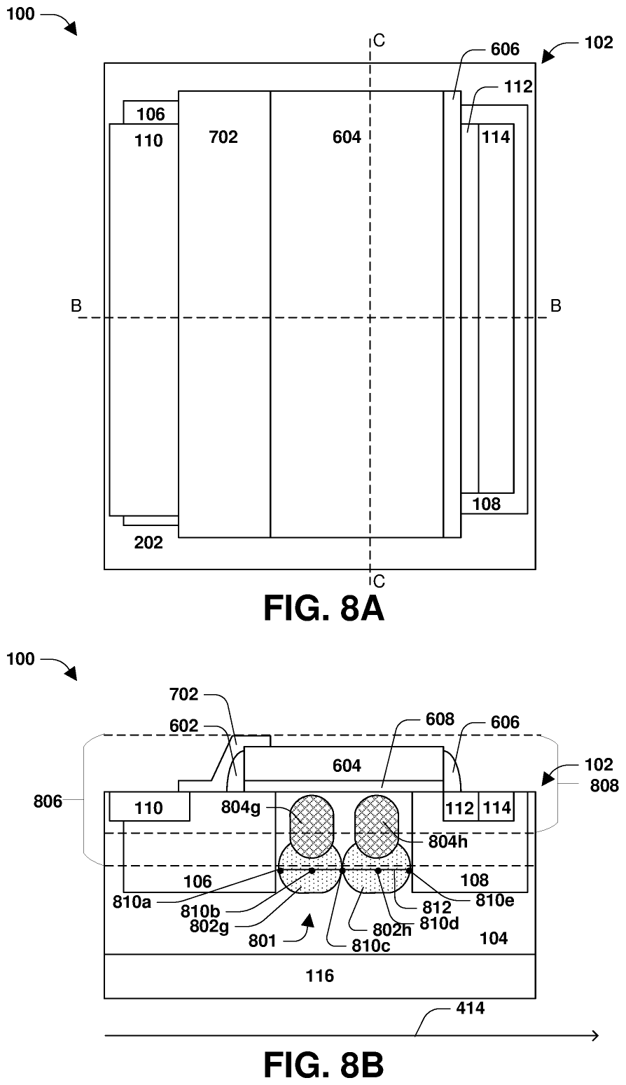

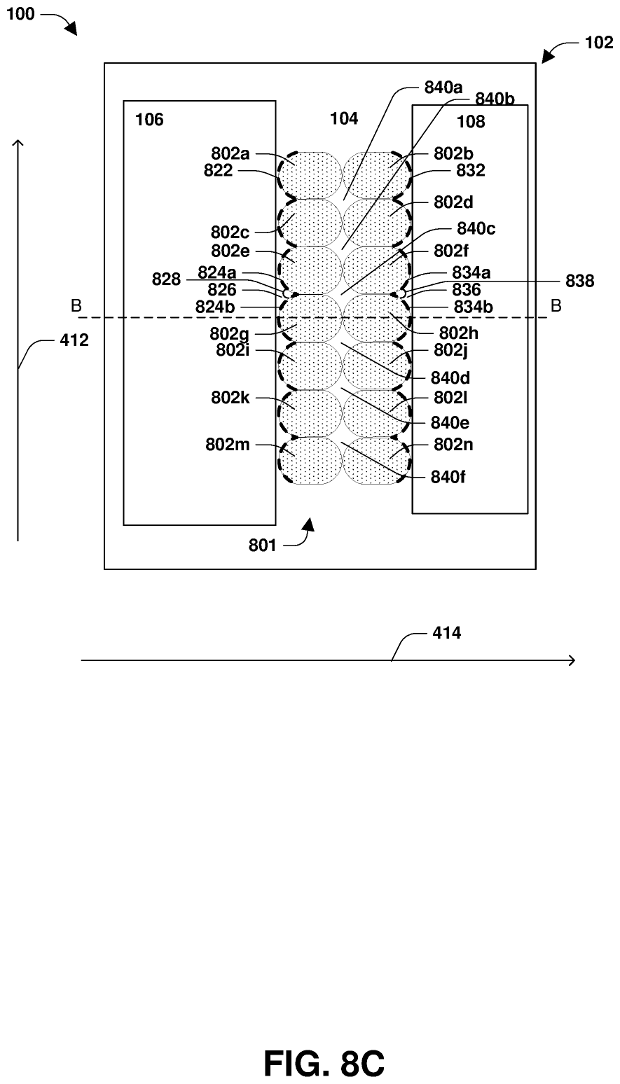

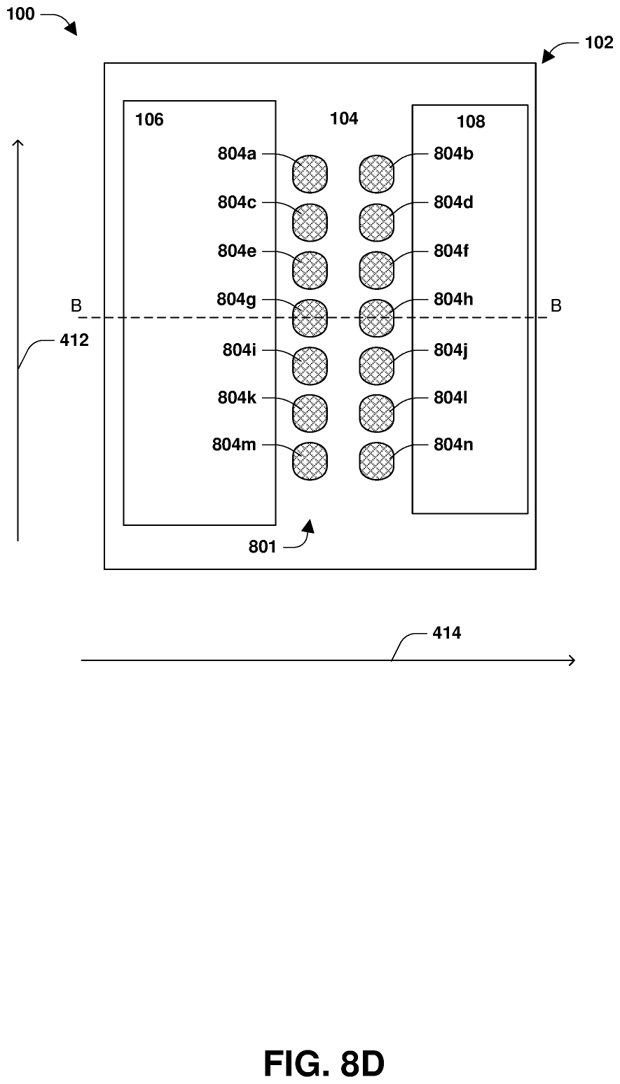

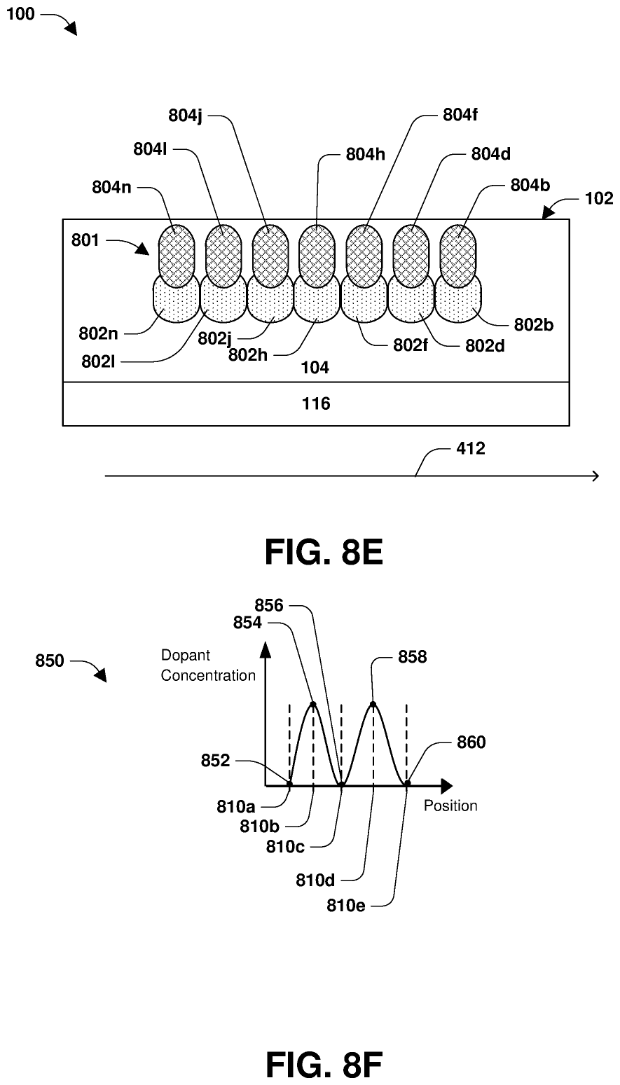

FIGS. 1A-8E illustrate a semiconductor device 100 at various stages of fabrication, in accordance with some embodiments. FIGS. 1A, 2A, 3A, 4A, 5A, 6A, 7A, and 8A illustrate top views of the semiconductor device 100 at various stages of fabrication. FIGS. 1B, 2B, 3B, 4B, 5B, 6B, 7B, and 8B illustrate cross-sectional views of the semiconductor device 100 taken along lines B-B of FIGS. 1A, 2A, 3A, 4A, 5A, 6A, 7A, and 8A, respectively. FIGS. 5C and 8E illustrate cross-sectional views of the semiconductor device 100 taken along lines C-C of FIGS. 5A and 8A, respectively.

In some embodiments, the semiconductor device 100 comprises a transistor. The transistor comprises a laterally diffused metal oxide semiconductor (LDMOS) transistor. Other transistor types of the transistor are within the scope of the present disclosure, such as including, but not limited to, at least one of a field-effect transistor (FET), a metal-oxide-semiconductor FET (MOSFET), a metal-insulator-semiconductor FET (MISFET), a metal-semiconductor FET (MESFET), an insulated-gate FET (IGFET), an insulated-gate bipolar transistor (IGBT), a high-electron mobility transistor (HEMT), a heterostructure FET (HFET), a modulation-doped FET (MODFET), or a different type of transistor.

FIGS. 1A and 1B illustrate the semiconductor device 100 according to some embodiments. In some embodiments, the semiconductor device 100 comprises a semiconductor body 102. The semiconductor body 102 comprises at least one of a substrate, an epitaxial layer, a silicon-on-insulator (SOI) structure, a wafer, or a die formed from a wafer. The semiconductor body 102 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable material. The semiconductor body 102 comprises at least one of monocrystalline silicon, crystalline silicon with a <100> crystallographic orientation, crystalline silicon with a <110> crystallographic orientation, crystalline silicon with a <111> crystallographic orientation or other suitable material. Other structures and/or configurations of the semiconductor body 102 are within the scope of the present disclosure. In some embodiments, the semiconductor body 102 comprises at least one of dopants of a first conductivity type or dopants of a second conductivity type. In some embodiments, the first conductivity type is p-type and the second conductivity type is n-type. In some embodiments, the semiconductor body 102 comprises p-type dopants comprising at least one of boron dopants, aluminum dopants, gallium dopants, beryllium dopants, or other p-type dopants. In some embodiments, the semiconductor body 102 comprises at least one of a p-type substrate or a p-type epitaxial layer. In some embodiments, the semiconductor body 102 comprises n-type dopants comprising at least one of nitrogen dopants, arsenic dopants, phosphorus dopants, or other n-type dopants. In some embodiments, the semiconductor body 102 comprises at least one of an n-type substrate or an n-type epitaxial layer.

In some embodiments, the semiconductor device 100 comprises at least one of a first doped region 106, a second doped region 108, a fourth doped region 110, a fifth doped region 104, a sixth doped region 112, a seventh doped region 114, or an eighth doped region 116. In some embodiments, the semiconductor device 100 comprises a drain region 120 (an example of which is outlined with a dashed line in FIG. 1B) comprising at least one of (i) at least some of the fifth doped region 104, (ii) at least some of the first doped region 106, (iii) at least some of the fourth doped region 110, or (iv) other portion of the semiconductor device 100. In some embodiments, the semiconductor device 100 comprises a source region 122 (an example of which is outlined with a dashed line in FIG. 1B) comprising at least one of (i) at least some of the sixth doped region 112, (ii) at least some of the seventh doped region 114, or (iii) other portion of the semiconductor device 100. In some embodiments, the semiconductor device 100 comprises a channel region 124 (an example of which is outlined with a dashed line in FIG. 1B) comprising at least one of (i) at least some of the second doped region 108 or (ii) other portion of the semiconductor device 100.

In some embodiments, dopants of the first doped region 106 comprise at least one of dopants of the first conductivity type or dopants of the second conductivity type. In some embodiments, the dopants are introduced to the first doped region 106 via at least one of ion implantation, molecular diffusion, or other suitable techniques. In some embodiments, the first doped region 106 comprises p-type dopants comprising at least one of boron dopants, aluminum dopants, gallium dopants, beryllium dopants, or other p-type dopants. In some embodiments, the first doped region 106 comprises n-type dopants comprising at least one of nitrogen dopants, arsenic dopants, phosphorus dopants, or other n-type dopants. In some embodiments, the first doped region 106 comprises a shallow well, such as a shallow n-well (SH_N) or a shallow p-well (SH_P).

In some embodiments, dopants of the second doped region 108 comprise at least one of dopants of the first conductivity type or dopants of the second conductivity type. In some embodiments, the dopants are introduced to the second doped region 108 via at least one of ion implantation, molecular diffusion, or other suitable techniques. In some embodiments, the second doped region 108 comprises p-type dopants comprising at least one of boron dopants, aluminum dopants, gallium dopants, beryllium dopants, or other p-type dopants. In some embodiments, the second doped region 108 comprises n-type dopants comprising at least one of nitrogen dopants, arsenic dopants, phosphorus dopants, or other n-type dopants. In some embodiments, the second doped region 108 comprises a high voltage body region, such as a high voltage p-body (HVPB) region or a high voltage n-body (HVNB) region.

In some embodiments, dopants of the fourth doped region 110 comprise at least one of dopants of the first conductivity type or dopants of the second conductivity type. In some embodiments, the dopants are introduced to the fourth doped region 110 via at least one of ion implantation, molecular diffusion, or other suitable techniques. In some embodiments, the fourth doped region 110 comprises p-type dopants comprising at least one of boron dopants, aluminum dopants, gallium dopants, beryllium dopants, or other p-type dopants. In some embodiments, the fourth doped region 110 comprises n-type dopants comprising at least one of nitrogen dopants, arsenic dopants, phosphorus dopants, or other n-type dopants. In some embodiments, dopants of the fourth doped region 110 are of the same conductivity type as dopants of the first doped region 106, wherein a concentration of the dopants of the fourth doped region 110 is greater than a concentration of the dopants of the first doped region 106.

In some embodiments, dopants of the fifth doped region 104 comprise at least one of dopants of the first conductivity type or dopants of the second conductivity type. In some embodiments, the dopants are introduced to the fifth doped region 104 via at least one of ion implantation, molecular diffusion, or other suitable techniques. In some embodiments, the fifth doped region 104 comprises p-type dopants comprising at least one of boron dopants, aluminum dopants, gallium dopants, beryllium dopants, or other p-type dopants. In some embodiments, the fifth doped region 104 comprises n-type dopants comprising at least one of nitrogen dopants, arsenic dopants, phosphorus dopants, or other n-type dopants. In some embodiments, the fifth doped region 104 comprises a high voltage well, such as a high voltage n-well (HVNW) or a high voltage p-well (HVPW).

In some embodiments, dopants of the sixth doped region 112 comprise at least one of dopants of the first conductivity type or dopants of the second conductivity type. In some embodiments, the dopants are introduced to the sixth doped region 112 via at least one of ion implantation, molecular diffusion, or other suitable techniques. In some embodiments, the sixth doped region 112 comprises p-type dopants comprising at least one of boron dopants, aluminum dopants, gallium dopants, beryllium dopants, or other p-type dopants. In some embodiments, the sixth doped region 112 comprises n-type dopants comprising at least one of nitrogen dopants, arsenic dopants, phosphorus dopants, or other n-type dopants. In some embodiments, dopants of the sixth doped region 112 are of a different conductivity type than dopants of the second doped region 108. In some embodiments, a portion of the semiconductor body 102 is counter-doped to form the sixth doped region 112.

In some embodiments, dopants of the seventh doped region 114 comprise at least one of dopants of the first conductivity type or dopants of the second conductivity type. In some embodiments, the dopants are introduced to the seventh doped region 114 via at least one of ion implantation, molecular diffusion, or other suitable techniques. In some embodiments, the seventh doped region 114 comprises p-type dopants comprising at least one of boron dopants, aluminum dopants, gallium dopants, beryllium dopants, or other p-type dopants. In some embodiments, the seventh doped region 114 comprises n-type dopants comprising at least one of nitrogen dopants, arsenic dopants, phosphorus dopants, or other n-type dopants. In some embodiments, dopants of the seventh doped region 114 are of the same conductivity type as dopants of the second doped region 108, wherein a concentration of the dopants of the seventh doped region 114 is greater than a concentration of the dopants of the second doped region 108.

In some embodiments, dopants of the eighth doped region 116 comprise at least one of dopants of the first conductivity type or dopants of the second conductivity type. In some embodiments, the dopants are introduced to the eighth doped region 116 via at least one of ion implantation, molecular diffusion, or other suitable techniques. In some embodiments, the eighth doped region 116 comprises p-type dopants comprising at least one of boron dopants, aluminum dopants, gallium dopants, beryllium dopants, or other p-type dopants. In some embodiments, the eighth doped region 116 comprises n-type dopants comprising at least one of nitrogen dopants, arsenic dopants, phosphorus dopants, or other n-type dopants. In some embodiments, the eighth doped region 116 comprises a buried layer, such as an n-type buried layer (NBL) or a p-type buried layer (PBL).

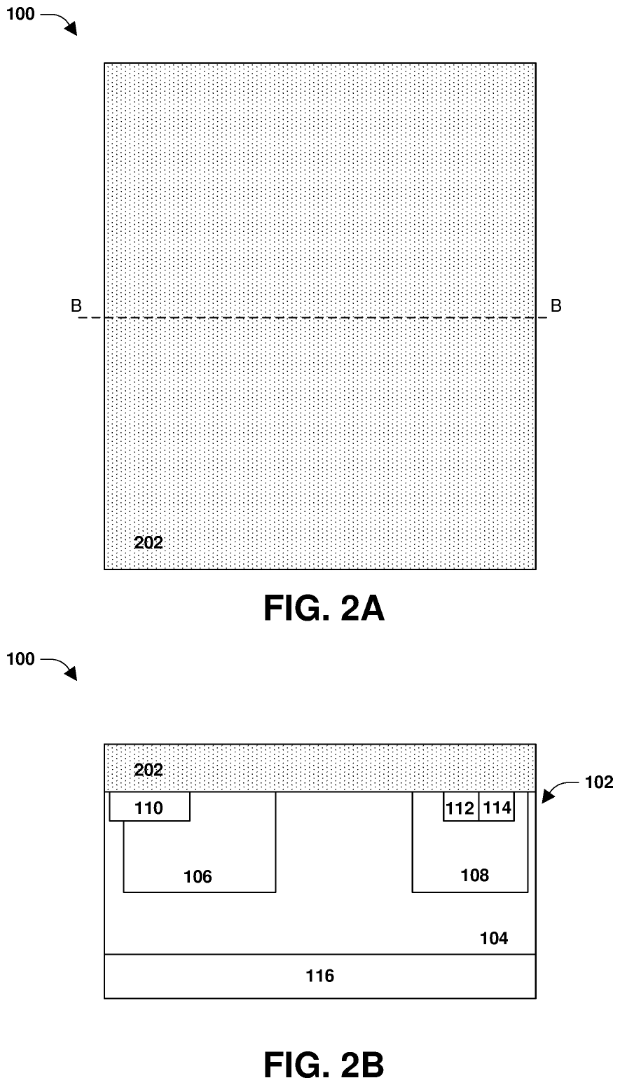

FIGS. 2A and 2B illustrate a first photoresist 202 formed over the semiconductor body 102, according to some embodiments. The first photoresist 202 overlies the semiconductor body 102. The first photoresist 202 is in direct contact or indirect contact with a top surface of the semiconductor body 102. When a first feature is in indirect contact with a second feature, one or more additional features may be formed between the first feature and the second feature. The first photoresist 202 is formed by at least one of physical vapor deposition (PVD), sputtering, chemical vapor deposition (CVD), low pressure CVD (LPCVD), atomic layer chemical vapor deposition (ALCVD), ultrahigh vacuum CVD (UHVCVD), reduced pressure CVD (RPCVD), atomic layer deposition (ALD), molecular beam epitaxy (MBE), liquid phase epitaxy (LPE), spin on, growth, or other suitable techniques.

In some embodiments, the first photoresist 202 comprises a light-sensitive material, where properties, such as solubility, of the first photoresist 202 are affected by light. The first photoresist 202 is a negative photoresist or a positive photoresist. With respect to a negative photoresist, regions of the negative photoresist become insoluble when illuminated by a light source, such that application of a solvent to the negative photoresist during a subsequent development stage removes non-illuminated regions of the negative photoresist. A pattern formed in the negative photoresist is thus a negative of a pattern defined by opaque regions of a template, such as a mask, between the light source and the negative photoresist. In a positive photoresist, illuminated regions of the positive photoresist become soluble and are removed via application of a solvent during development. Thus, a pattern formed in the positive photoresist is a positive image of opaque regions of the template, such as a mask, between the light source and the positive photoresist.

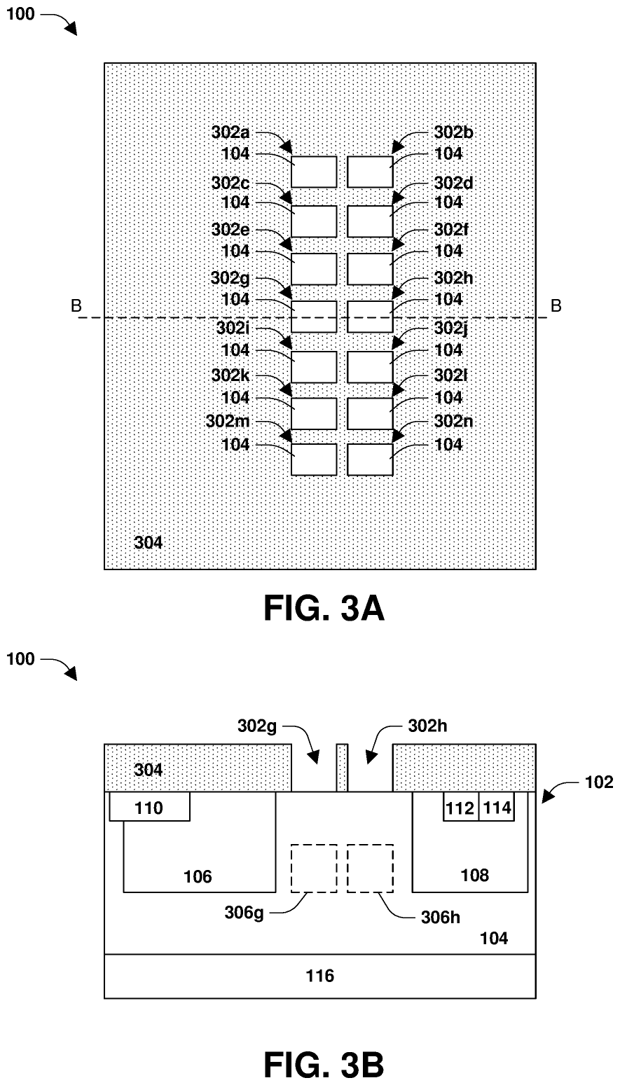

FIGS. 3A and 3B illustrate a first patterned photoresist 304 formed from the first photoresist 202, according to some embodiments. In some embodiments, the first patterned photoresist 304 defines a first set of openings. In some embodiments, the first set of openings comprises at least one of a first opening 302a, a second opening 302b, a third opening 302c, a fourth opening 302d, a fifth opening 302e, a sixth opening 302f, a seventh opening 302g, an eighth opening 302h, a ninth opening 302i, a tenth opening 302j, an eleventh opening 302k, a twelfth opening 302l, a thirteenth opening 302m, a fourteenth opening 302n, or one or more other openings. Even though 14 openings defined in the first patterned photoresist 304 are depicted in FIG. 3A, any number of openings in the first patterned photoresist 304 are contemplated. The seventh opening 302g and the eighth opening 302h are depicted in FIG. 3B, in accordance with some embodiments. Other arrangements of the first patterned photoresist 304 and/or the first set of openings other than the example arrangement shown in FIGS. 3A-3B are within the scope of the present disclosure.

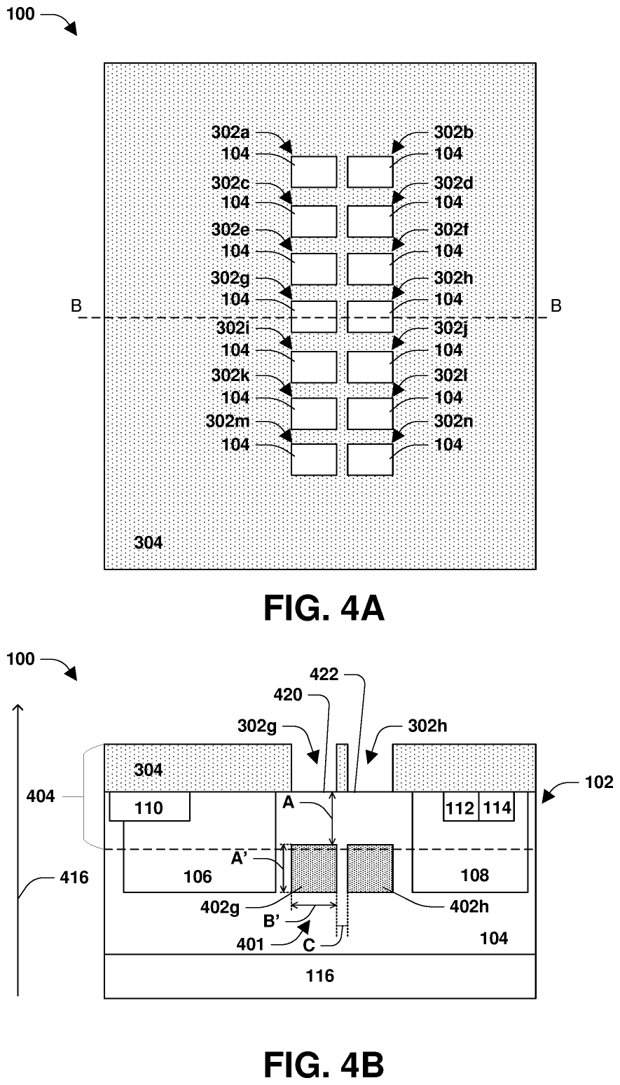

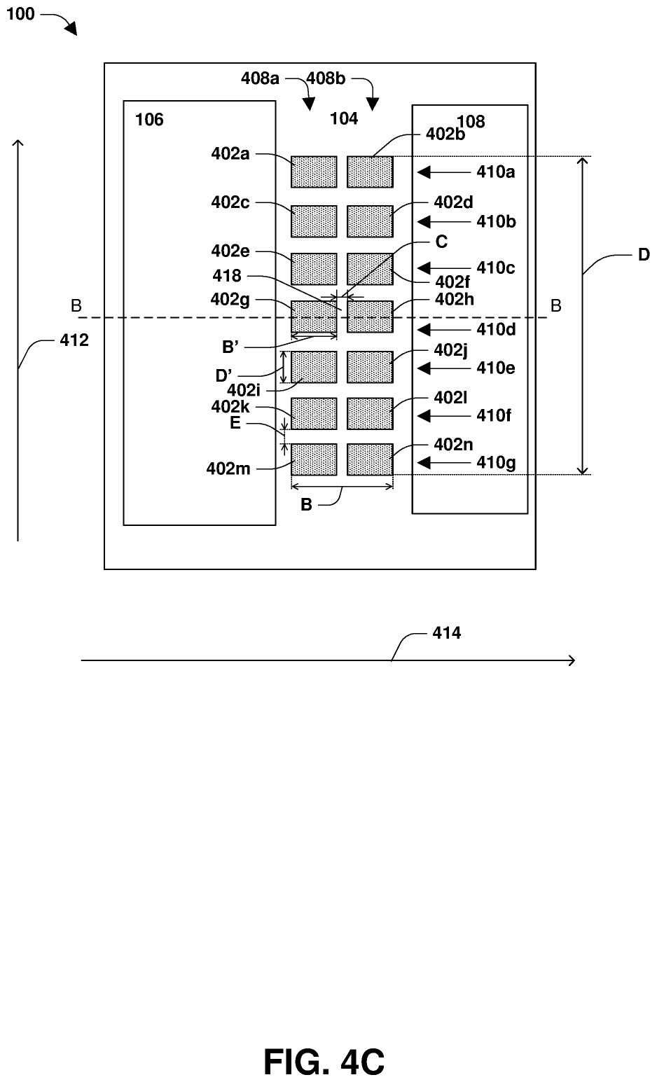

FIGS. 4A-4C illustrate use of the first patterned photoresist 304 to form a third doped region 401, according to some embodiments. FIG. 4C illustrates a top view of the semiconductor device 100 without a top portion 404 (shown in FIG. 4B) of the semiconductor device 100 to show portions 402a-402n of the third doped region 401, in accordance with some embodiments. In some embodiments, the third doped region 401 is formed by performing a first doping process comprising at least one of ion implantation, molecular diffusion, or other suitable techniques. In some embodiments, forming the third doped region 401 comprises implanting a distribution of dopants into a locale of the semiconductor body 102 to form a portion of the third doped region 401. In some embodiments, the distribution of dopants is implanted through an opening of the first set of openings defined by the first patterned photoresist 304 into the locale.

In some embodiments, dopants of the third doped region 401 comprise at least one of dopants of the first conductivity type or dopants of the second conductivity type. In some embodiments, the dopants are introduced to the third doped region 401 via at least one of ion implantation, molecular diffusion, or other suitable techniques. In some embodiments, the third doped region 401 comprises p-type dopants comprising at least one of boron dopants, aluminum dopants, gallium dopants, beryllium dopants, or other p-type dopants. In some embodiments, the third doped region 401 comprises n-type dopants comprising at least one of nitrogen dopants, arsenic dopants, phosphorus dopants, or other n-type dopants. In some embodiments, the third doped region 401 comprises at least one of fluoride dopants, sulfur dopants, or other dopants. In some embodiments, the third doped region 401 comprises a double diffusion region, such as a p-type double diffusion (PDD) region or an n-type double diffusion (NDD) region. In some embodiments, a double diffusion region is a region that is doped with at least two types of dopants, such as at least two types of n-type dopants, at least two types of p-type dopants, a combination of n-type dopants and p-type dopants.

In some embodiments, the third doped region 401 comprises a first set of portions. In some embodiments (e.g., as shown in FIG. 4C), the first set of portions comprises at least one of a first portion 402a of the third doped region 401, a second portion 402b of the third doped region 401, a third portion 402c of the third doped region 401, a fourth portion 402d of the third doped region 401, a fifth portion 402e of the third doped region 401, a sixth portion 402f of the third doped region 401, a seventh portion 402g of the third doped region 401, an eighth portion 402h of the third doped region 401, a ninth portion 402i of the third doped region 401, a tenth portion 402j of the third doped region 401, an eleventh portion 402k of the third doped region 401, a twelfth portion 402l of the third doped region 401, a thirteenth portion 402m of the third doped region 401, a fourteenth portion 402n of the third doped region 401, or one or more other portions. Even though 14 portions of the first set of portions are depicted in FIG. 4C, any number of portions of the first set of portions are contemplated. Other arrangements of the third doped region 401 other than the example arrangement shown in FIGS. 4A-4C are within the scope of the present disclosure.

In some embodiments, the first doping process (performed to form the third doped region 401) comprises directing dopants through one or more portions of the top surface of the semiconductor body 102. In some embodiments, the first patterned photoresist 304 inhibits dopants from entering a portion of the top surface of the semiconductor body 102 that is covered by the first patterned photoresist 304. In some embodiments, the first doping process comprises directing dopants through a portion of the top surface of the semiconductor body 102 that is exposed by an opening of the first set of openings defined by the first patterned photoresist 304. In some embodiments, a depth to which dopants penetrate into the semiconductor body 102 in the first doping process is controlled by increasing or decreasing a voltage and/or implantation energy level used to direct the dopants into the semiconductor device 100.

In some embodiments, the first doping process comprises at least one of (i) a first implanting act comprising implanting a first distribution of dopants into a first locale of the semiconductor body 102 to form the first portion 402a of the third doped region 401, (ii) a second implanting act comprising implanting a second distribution of dopants into a second locale of the semiconductor body 102 to form the second portion 402b of the third doped region 401, (iii) a third implanting act comprising implanting a third distribution of dopants into a third locale of the semiconductor body 102 to form the third portion 402c of the third doped region 401, (iv) a fourth implanting act comprising implanting a fourth distribution of dopants into a fourth locale of the semiconductor body 102 to form the fourth portion 402d of the third doped region 401, (v) a fifth implanting act comprising implanting a fifth distribution of dopants into a fifth locale of the semiconductor body 102 to form the fifth portion 402e of the third doped region 401, (vi) a sixth implanting act comprising implanting a sixth distribution of dopants into a sixth locale of the semiconductor body 102 to form the sixth portion 402f of the third doped region 401, (vii) a seventh implanting act comprising implanting a seventh distribution of dopants into a seventh locale 306g (shown in FIG. 3B) of the semiconductor body 102 to form the seventh portion 402g (shown in FIGS. 4B and 4C) of the third doped region 401, (viii) an eighth implanting act comprising implanting an eighth distribution of dopants into an eighth locale 306h (shown in FIG. 3B) of the semiconductor body 102 to form the eighth portion 402h (shown in FIGS. 4B and 4C) of the third doped region 401, (ix) a ninth implanting act comprising implanting a ninth distribution of dopants into a ninth locale of the semiconductor body 102 to form the ninth portion 402i of the third doped region 401, (x) a tenth implanting act comprising implanting a tenth distribution of dopants into a tenth locale of the semiconductor body 102 to form the tenth portion 402j of the third doped region 401, (xi) an eleventh implanting act comprising implanting an eleventh distribution of dopants into an eleventh locale of the semiconductor body 102 to form the eleventh portion 402k of the third doped region 401, (xii) a twelfth implanting act comprising implanting a twelfth distribution of dopants into a twelfth locale of the semiconductor body 102 to form the twelfth portion 402l of the third doped region 401, (xiii) a thirteenth implanting act comprising implanting a thirteenth distribution of dopants into a thirteenth locale of the semiconductor body 102 to form the thirteenth portion 402m of the third doped region 401, (xiv) a fourteenth implanting act comprising implanting a fourteenth distribution of dopants into a fourteenth locale of the semiconductor body 102 to form the fourteenth portion 402n of the third doped region 401, or (xv) one or more other implanting acts comprising implanting one or more other distribution of dopants into one or more other locales of the semiconductor body 102 to form one or more other portions of the third doped region 401. In some embodiments, at least some implanting acts of the first doping process are performed concurrently, such as where the first implanting act and the second implanting act are performed concurrently. In some embodiments, at least some implanting acts of the first doping process are performed sequentially, such as where the first implanting act is performed after or before the second implanting act. In some embodiments, at least one of the first locale, the second locale, the third locale, the fourth locale, the fifth locale, the sixth locale, the seventh locale, the eighth locale, the ninth locale, the tenth locale, the eleventh locale, the twelfth locale, the thirteenth locale, or the fourteenth locale is counter doped via the first doping process to form the third doped region 401. In some embodiments, a concentration of dopants of the third doped region 401 is between about 10E+11 to about 99E+15.

In some embodiments, portions of the third doped region 401 are arranged in a matrix arrangement comprising a first set of rows and a first set of columns. In some embodiments, the first set of rows (shown in FIG. 4C) comprises a first row 410a (e.g., comprising the first portion 402a and the second portion 402b), a second row 410b, a third row 410c, a fourth row 410d, a fifth row 410e, a sixth row 410f and a seventh row 410g. Embodiments are contemplated in which the first set of rows comprises merely a single row or any other number of rows. In some embodiments, the first set of columns (shown in FIG. 4C) comprises a first column 408a and a second column 408b. Embodiments are contemplated in which the first set of columns comprises merely a single column or any other number of columns.

In some embodiments, at least some of the first set of portions of the third doped region 401 are coplanar. In some embodiments, at least some of the first set of portions of the third doped region 401 are spaced apart from each other. In some embodiments, the eleventh portion 402k (of the sixth row 410f) is spaced apart from the thirteenth portion 402m (of the seventh row 410g) by a distance E (shown in FIGS. 4C and 5C). In some embodiments, the distance E is greater than zero. In some embodiments, the distance E corresponds to a range of distances ranging from a first minimum distance to a first maximum distance. In some embodiments, the first minimum distance is greater than zero. In some embodiments, the first maximum distance is greater than the first minimum distance by at most about 1 micrometer. In some embodiments, each pair of adjacent portions in a column of the first set of columns are spaced apart from each other by about the distance E (and/or by a distance between about the first minimum distance to about the first maximum distance). In some embodiments, the distance E corresponds to a distance (or range of distances) by which two adjacent portions of the first set of portions are separated from each other along a first horizontal axis 412 (shown in FIG. 4C). In some embodiments, among pairs of adjacent portions (of the first set of portions) that are separated from each other along the first horizontal axis 412, some or all of the pairs are separated from each other by about the distance E (and/or by a distance between about the first minimum distance to about the first maximum distance).

In some embodiments, the seventh portion 402g (of the fourth row 410d) is spaced apart from the eighth portion 402h (of the fourth row 410d) by a distance C (shown in FIGS. 4B and 4C). In some embodiments, the seventh portion 402g is separated from the eighth portion 402h by a portion 418 of the semiconductor body 102. In some embodiments, dopants of the portion 418 of the semiconductor body 102 are of a different conductivity type than dopants of the third doped region 401, such as where dopants of the portion 418 are n-type dopants and dopants of the third doped region 401 are p-type dopants or where dopants of the portion 418 are p-type dopants and dopants of the third doped region 401 are n-type dopants. In some embodiments, the distance C is greater than zero. In some embodiments, the distance C corresponds to a range of distances ranging from a second minimum distance to a second maximum distance. In some embodiments, the second minimum distance is greater than zero. In some embodiments, the second maximum distance is greater than the second minimum distance by at most about 1 micrometer. In some embodiments, each pair of adjacent portions in a row of the first set of rows are spaced apart from each other by about the distance C (and/or by a distance between about the second minimum distance to about the second maximum distance). In some embodiments, the distance C corresponds to a distance (or range of distances) by which two adjacent portions of the first set of portions are separated from each other along a second horizontal axis 414 (shown in FIG. 4C). In some embodiments, among pairs of adjacent portions (of the first set of portions) that are separated from each other along the second horizontal axis 414, some or all of the pairs are separated from each other by about the distance C (and/or by a distance between about the second minimum distance to about the second maximum distance).

In some embodiments, the seventh portion 402g (of the fourth row 410d shown in FIG. 4C) has a length B′ (shown in FIGS. 4B and 4C). In some embodiments, the length B′ is greater than zero. In some embodiments, the length B′ corresponds to a range of lengths ranging from a first minimum length to a first maximum length. In some embodiments, the first minimum length is greater than zero. In some embodiments, the first maximum length is greater than the first minimum length by at most about 1 micrometer. In some embodiments, some or all portions of the first set of portions of the third doped region 401 have the length B′ (and/or a length along the second horizontal axis 414 that is between about the first minimum length to about the first maximum length). In some embodiments, the length B′ corresponds to a length of a portion of the first set of portions along the second horizontal axis 414 (shown in FIG. 4C).

In some embodiments, the ninth portion 402i (of the fifth row 410e shown in FIG. 4C) has a width D′ (shown in FIGS. 4C and 5C). In some embodiments, the width D′ is greater than zero. In some embodiments, the width D′ corresponds to a range of widths ranging from a first minimum width to a first maximum width. In some embodiments, the first minimum width is greater than zero. In some embodiments, the first maximum width is greater than the first minimum width by at most about 1 micrometer. In some embodiments, some or all portions of the first set of portions of the third doped region 401 have the width D′ (and/or a width along the first horizontal axis 412 that is between about the first minimum width to about the first maximum width). In some embodiments, the width D′ corresponds to a length of a portion of the first set of portions along the first horizontal axis 412 (shown in FIG. 4C).

In some embodiments, the seventh portion 402g has a height A′ (shown in FIG. 4B). In some embodiments, the height A′ is greater than zero. In some embodiments, the height A′ corresponds to a range of heights ranging from a first minimum height to a first maximum height. In some embodiments, the first minimum height is greater than zero. In some embodiments, the first maximum height is greater than the first minimum height by at most about 1 micrometer. In some embodiments, some, or all portions of the first set of portions of the third doped region 401 have the height A′ (and/or a height that is between about the first minimum height to about the first maximum height). In some embodiments, the height A′ corresponds to a length of a portion of the first set of portions along a vertical axis 416 (shown in FIG. 4B).

In some embodiments, the seventh portion 402g has a depth A (shown in FIG. 4B). In some embodiments, the depth A is greater than zero. In some embodiments, the depth A corresponds to a range of depths ranging from a first minimum depth to a first maximum depth. In some embodiments, the first minimum depth is greater than zero. In some embodiments, the first maximum depth is greater than the first minimum depth by at most about 1 micrometer. In some embodiments, some or all portions of the first set of portions of the third doped region 401 have the depth A (and/or a depth that is between about the first minimum depth to about the first maximum depth). In some embodiments, the depth A corresponds to a distance (along the vertical axis 416, for example) between the top surface of the semiconductor body 102 and a portion of the first set of portions. In some embodiments, at least one of the depth A or the height A′ (shown in FIG. 4B) of one or more portions of the first set of portions of the third doped region 401 are controlled by controlling at least one of a voltage, an implantation energy level, an implantation dose, etc. of the first doping process.

In some embodiments, the third doped region 401 has a doped region length B (shown in FIG. 4C), such as a total length of the third doped region 401 along the second horizontal axis 414. In some embodiments, the third doped region 401 has a doped region width D (shown in FIG. 4C), such as a total length of the third doped region 401 along the first horizontal axis 412.

In some embodiments, the first doping process (performed to form the third doped region 401) is performed according to a doping map. In some embodiments, the doping map is indicative of dimensions of the first set of portions of the third doped region 401. In some embodiments, the doping map is generated based upon at least one of (i) a first design function: 0<A′/(A′+A)<1, where A′ corresponds to the height A′ of one, some, or all portions of the first set of portions of the third doped region 401 and A corresponds to the depth A of one, some, or all portions of the first set of portions of the third doped region 401, (ii) a second design function: 0<M×B′/[M×B′+(M−1)×C]<1, where M corresponds to a number of columns of the first set of columns, C corresponds to the distance C (shown in FIGS. 4B and 4C), and/or B′ corresponds to the length B′ (along the second horizontal axis 414) of one, some, or all portions of the first set of portions of the third doped region 401, or (iii) a third design function: 0<N×D′/[N×D′+(N−1)×E]≤1, where N corresponds to a number of rows of the first set of rows, E corresponds to the distance E (shown in FIG. 4C), and/or D′ corresponds to the width D′ (along the first horizontal axis 412) of one, some, or all portions of the first set of portions of the third doped region 401. In some embodiments, dimensions indicated by the doping map for the third doped region 401 satisfy at least one of the first design function, the second design function, or the third design function. In some embodiments, dimensions of the third doped region 401 satisfy at least one of the first design function, the second design function, or the third design function.

In FIG. 4B, portions 402g and 402h of the third doped region are shown to be rectangular-shaped (relative to the cross-sectional view of FIG. 4B). Other shapes, such as at least one of square, triangular, rectangular, trapezoidal, etc. of portions of the third doped region (relative to the cross-sectional view of FIG. 4B) are within the scope of the present disclosure.

In FIG. 4C, portions 402a-402n of the third doped region are shown to be rectangular-shaped (relative to the top view of FIG. 4C). Other shapes, such as at least one of square, triangular, rectangular, trapezoidal, etc. of portions of the third doped region (relative to the top view of FIG. 4C) are within the scope of the present disclosure.

FIGS. 5A-5C illustrate removal of the first patterned photoresist 304, according to some embodiments. In some embodiments, the first patterned photoresist 304 is removed after the third doped region 401 is formed. The first patterned photoresist 304 is removed by at least one of a washing process to wash the first patterned photoresist 304 away, stripping the first patterned photoresist 304 away, etching the first patterned photoresist 304, chemical mechanical planarization (CMP), or other suitable techniques.

In FIG. 5C, portions 402b, 402d, 402f, 402h, 402j, 4021, and 402n of the third doped region are shown to be rectangular-shaped (relative to the cross-sectional view of FIG. 5C. Other shapes, such as at least one of square, triangular, rectangular, trapezoidal, etc. of portions of the third doped region (relative to the cross-sectional view of FIG. 5C) are within the scope of the present disclosure.

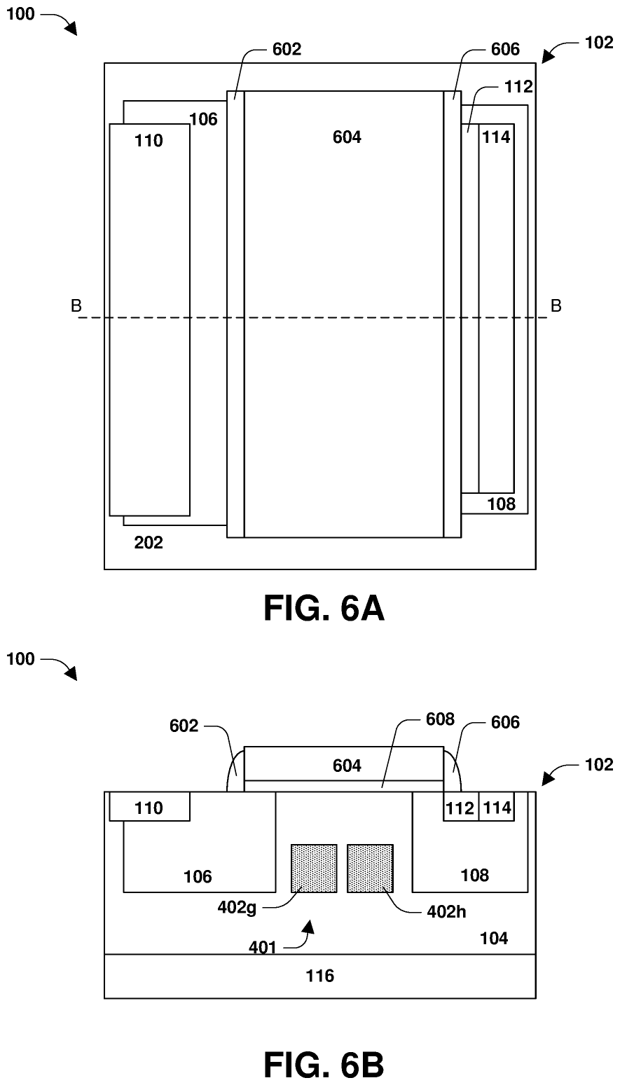

FIGS. 6A and 6B illustrate a first gate structure formed over the semiconductor body 102, according to some embodiments. The first gate structure overlies the semiconductor body 102. The first gate structure is in direct contact or indirect contact with the top surface of the semiconductor body 102. In some embodiments, the first gate structure overlies the third doped region 401. In some embodiments, the first gate structure comprises at least one of a gate electrode 604, a gate dielectric layer 608, a first gate spacer 602, or a second gate spacer 606. In some embodiments, the gate dielectric layer 608 separates the gate electrode 604 from the semiconductor body 102.

In some embodiments, the gate dielectric layer 608 is formed by at least one of PVD, sputtering, CVD, LPCVD, ALCVD, UHVCVD, RPCVD, ALD, MBE, LPE, spin on, growth, or other suitable techniques. In some embodiments, the gate dielectric layer 608 comprises at least one of a semiconductor material, an oxide, silicon dioxide, Al₂O₃, HfO, HfO₂, ZrO, ZrO₂, ZrSiO, YO, Y₂O₃, LaO, La₂O₅, GdO, Gd₂O₅, TiO, TiO₂, TiSiO, TaO, Ta₂O₅, TaSiO, HfErO, HfLaO, HfYO, HfGdO, HfAlO, HfZrO, HfTiO, HfTaO, HfSiO, SrTiO, ZrSiON, HfZrTiO, HfZrSiON, HfZrLaO, HfZrAlO, or other suitable material. In some embodiments, the gate electrode 604 is formed over the gate dielectric layer 608 by at least one of PVD, sputtering, CVD, LPCVD, ALCVD, UHVCVD, RPCVD, ALD, MBE, LPE, spin on, growth, or other suitable techniques. In some embodiments, the gate electrode 604 comprises at least one of polysilicon, one or more metals, or other suitable material. In some embodiments, at least one of the first gate spacer 602 or the second gate spacer 606 is formed by at least one of PVD, sputtering, CVD, LPCVD, ALCVD, UHVCVD, RPCVD, ALD, MBE, LPE, spin on, growth, or other suitable techniques.

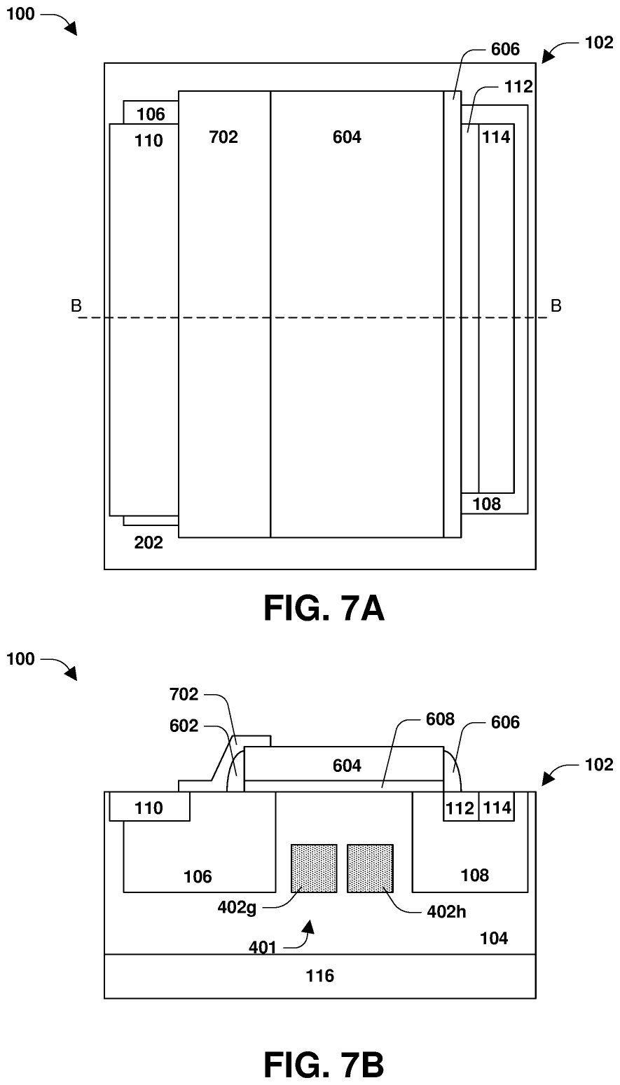

FIGS. 7A and 7B illustrate a first protective structure 702 formed over at least one of the semiconductor body 102 or the first gate structure, according to some embodiments. The first protective structure 702 overlies the semiconductor body 102. The first protective structure 702 is in direct contact or indirect contact with the top surface of the semiconductor body 102. In some embodiments, the first protective structure 702 comprises at least one of resist protective oxide (RPO) or other suitable material. In some embodiments, the first protective structure 702 is formed by at least one of PVD, sputtering, CVD, LPCVD, ALCVD, UHVCVD, RPCVD, ALD, MBE, LPE, spin on, growth, or other suitable techniques.

In some embodiments, the semiconductor body 102 undergoes one or more thermal processes while the third doped region 401 is in the semiconductor body 102. In some embodiments, a thermal process of the one or more thermal processes comprises performing an anneal on the semiconductor body 102. In some embodiments, thermal energy introduced to the semiconductor body 102 and/or the third doped region 401 via a thermal process of the one or more thermal processes causes diffusion of dopants of the third doped region 401, which includes migration of dopants of the third doped region 401 from one or more first locales of the semiconductor body 102 to one or more second locales. In some embodiments, the diffusion and/or migration of the dopants of the third doped region 401 via the one or more thermal processes forms a diffused third doped region 801 (shown in FIGS. 8B-8E). In some embodiments, the diffusion and/or migration of the dopants of the third doped region 401 via the one or more thermal processes causes the third doped region 401 to expand into the diffused third doped region 801.

FIGS. 8A-8E illustrate the diffused third doped region 801 formed from the third doped region 401, according to some embodiments. In some embodiments, the diffused third doped region 801 comprises at least one of a first set of diffused portions or a second set of diffused portions over the first set of diffused portions. In some embodiments, the first set of diffused portions comprises diffused portions 802a-802n (shown in FIG. 8C). FIG. 8C illustrates a top view of the semiconductor device 100 without a top portion 806 (shown in FIG. 8B) of the semiconductor device 100 to show the diffused portions 802a-802n of the diffused third doped region 801, in accordance with some embodiments. In some embodiments, the second set of diffused portions comprises diffused portions 804a-804n (shown in FIG. 8d). FIG. 8D illustrates a top view of the semiconductor device 100 without a top portion 808 (shown in FIG. 8B) of the semiconductor device 100 to show the diffused portions 804a-804n of the diffused third doped region 801, in accordance with some embodiments.

In some embodiments, the first set of diffused portions comprises at least one of (i) a diffused portion 802a (shown in FIG. 8C) formed via diffusion (e.g., by the one or more thermal processes) of the first portion 402a of the third doped region 401, (ii) a diffused portion 802b formed via diffusion (e.g., by the one or more thermal processes) of the second portion 402b of the third doped region 401, (iii) a diffused portion 802c formed via diffusion (e.g., by the one or more thermal processes) of the third portion 402c of the third doped region 401, (iv) a diffused portion 802d formed via diffusion (e.g., by the one or more thermal processes) of the fourth portion 402d of the third doped region 401, (v) a diffused portion 802e formed via diffusion (e.g., by the one or more thermal processes) of the fifth portion 402e of the third doped region 401, (vi) a diffused portion 802f formed via diffusion (e.g., by the one or more thermal processes) of the sixth portion 402f of the third doped region 401, (vii) a diffused portion 802g formed via diffusion (e.g., by the one or more thermal processes) of the seventh portion 402g of the third doped region 401, (viii) a diffused portion 802h formed via diffusion (e.g., by the one or more thermal processes) of the eighth portion 402h of the third doped region 401, (ix) a diffused portion 802i formed via diffusion (e.g., by the one or more thermal processes) of the ninth portion 402i of the third doped region 401, (x) a diffused portion 802j formed via diffusion (e.g., by the one or more thermal processes) of the tenth portion 402j of the third doped region 401, (xi) a diffused portion 802k formed via diffusion (e.g., by the one or more thermal processes) of the eleventh portion 402k of the third doped region 401, (xii) a diffused portion 802l formed via diffusion (e.g., by the one or more thermal processes) of the twelfth portion 402l of the third doped region 401, (xiii) a diffused portion 802m formed via diffusion (e.g., by the one or more thermal processes) of the thirteenth portion 402m of the third doped region 401, (xiv) a diffused portion 802n formed via diffusion (e.g., by the one or more thermal processes) of the fourteenth portion 402n of the third doped region 401, or (xv) one or more other diffused portions.

In some embodiments, the second set of diffused portions comprises at least one of (i) a diffused portion 804a (shown in FIG. 8D) formed via diffusion (e.g., by the one or more thermal processes) of the first portion 402a of the third doped region 401, (ii) a diffused portion 804b formed via diffusion (e.g., by the one or more thermal processes) of the second portion 402b of the third doped region 401, (iii) a diffused portion 804c formed via diffusion (e.g., by the one or more thermal processes) of the third portion 402c of the third doped region 401, (iv) a diffused portion 804d formed via diffusion (e.g., by the one or more thermal processes) of the fourth portion 402d of the third doped region 401, (v) a diffused portion 804e formed via diffusion (e.g., by the one or more thermal processes) of the fifth portion 402e of the third doped region 401, (vi) a diffused portion 804f formed via diffusion (e.g., by the one or more thermal processes) of the sixth portion 402f of the third doped region 401, (vii) a diffused portion 804g formed via diffusion (e.g., by the one or more thermal processes) of the seventh portion 402g of the third doped region 401, (viii) a diffused portion 804h formed via diffusion (e.g., by the one or more thermal processes) of the eighth portion 402h of the third doped region 401, (ix) a diffused portion 804i formed via diffusion (e.g., by the one or more thermal processes) of the ninth portion 402i of the third doped region 401, (x) a diffused portion 804j formed via diffusion (e.g., by the one or more thermal processes) of the tenth portion 402j of the third doped region 401, (xi) a diffused portion 804k formed via diffusion (e.g., by the one or more thermal processes) of the eleventh portion 402k of the third doped region 401, (xii) a diffused portion 804l formed via diffusion (e.g., by the one or more thermal processes) of the twelfth portion 402l of the third doped region 401, (xiii) a diffused portion 804m formed via diffusion (e.g., by the one or more thermal processes) of the thirteenth portion 402m of the third doped region 401, (xiv) a diffused portion 804n formed via diffusion (e.g., by the one or more thermal processes) of the fourteenth portion 402n of the third doped region 401, or (xv) one or more other diffused portions. In some embodiments, a diffused portion of the second set of diffused portions comprises dopants implanted into the semiconductor body 102 by an implantation act of the first doping process.

In some embodiments, dopants of the first set of diffused portions are of the same conductivity type as dopants of the second set of diffused portions. In some embodiments, dopants of the diffused third doped region 801 are the same as (and/or are of the same conductivity type as) dopants of the third doped region 401. In some embodiments, a concentration of dopants of a diffused portion of the first set of diffused portions is greater than a concentration of dopants of a diffused portion of the second set of diffused portions. In some embodiments, at least one of (i) a concentration of dopants of the diffused portion 802a (shown in FIG. 8C) is greater than a concentration of dopants of the diffused portion 804a (shown in FIG. 8D), (ii) a concentration of dopants of the diffused portion 802b (shown in FIG. 8C) is greater than a concentration of dopants of the diffused portion 804b (shown in FIG. 8D), (iii) a concentration of dopants of the diffused portion 802c (shown in FIG. 8C) is greater than a concentration of dopants of the diffused portion 804c (shown in FIG. 8D), (iv) a concentration of dopants of the diffused portion 802d (shown in FIG. 8C) is greater than a concentration of dopants of the diffused portion 804d (shown in FIG. 8D), (v) a concentration of dopants of the diffused portion 802e (shown in FIG. 8C) is greater than a concentration of dopants of the diffused portion 804e (shown in FIG. 8D), (vi) a concentration of dopants of the diffused portion 802f (shown in FIG. 8C) is greater than a concentration of dopants of the diffused portion 804f (shown in FIG. 8D), (vii) a concentration of dopants of the diffused portion 802g (shown in FIGS. 8B and 8C) is greater than a concentration of dopants of the diffused portion 804g (shown in FIGS. 8B and 8D), (viii) a concentration of dopants of the diffused portion 802h (shown in FIGS. 8B and 8C) is greater than a concentration of dopants of the diffused portion 804h (shown in FIGS. 8B and 8D), (ix) a concentration of dopants of the diffused portion 802i (shown in FIG. 8C) is greater than a concentration of dopants of the diffused portion 804i (shown in FIG. 8D), (x) a concentration of dopants of the diffused portion 802j (shown in FIG. 8C) is greater than a concentration of dopants of the diffused portion 804j (shown in FIG. 8D), (xi) a concentration of dopants of the diffused portion 802k (shown in FIG. 8C) is greater than a concentration of dopants of the diffused portion 804k (shown in FIG. 8D), (xii) a concentration of dopants of the diffused portion 802l (shown in FIG. 8C) is greater than a concentration of dopants of the diffused portion 804l (shown in FIG. 8D), (xiii) a concentration of dopants of the diffused portion 802m (shown in FIG. 8C) is greater than a concentration of dopants of the diffused portion 804m (shown in FIG. 8D), or (xiv) a concentration of dopants of the diffused portion 802n (shown in FIG. 8C) is greater than a concentration of dopants of the diffused portion 804n (shown in FIG. 8D). In some embodiments, a diffused portion of the second set of diffused portions comprises dopants implanted into the semiconductor body 102 by an implantation act of the first doping process.

FIG. 8F illustrates a dopant concentration data structure 850 indicative of dopant concentrations of portions of the diffused third doped region 801 along a line 812 (solid line shown in FIG. 8B), according to some embodiments. In some embodiments, the diffused third doped region 801 comprises at least one of a portion 810a (shown in FIG. 8B) having a first concentration of dopants 852 (shown in FIG. 8F), a portion 810b having a second concentration of dopants 854, a portion 810c having a third concentration of dopants 856, a portion 810d having a fourth concentration of dopants 858, or a portion 810e having a fifth concentration of dopants 860. In some embodiments, the diffused third doped region 801 has a gradient such that a concentration of dopants changes along the line 812 extending through at least one of the portion 810a, the portion 810b, the portion 810c, the portion 810d, or the portion 810e. In some embodiments, a distance between the portion 810a and the portion 810e is greater than a distance between the portion 810a and the portion 810b. In some embodiments, the line 812 is parallel to the second horizontal axis 414. In some embodiments, along the line 812, at least one of the first concentration of dopants 852 is less than the second concentration of dopants 854, the second concentration of dopants 854 is greater than the third concentration of dopants 856, the third concentration of dopants 856 is less than the fourth concentration of dopants 858, or the fourth concentration of dopants 858 is greater than the fifth concentration of dopants 860. In some embodiments, the first concentration of dopants 852 corresponds to a first dip in dopant concentration (e.g., a first local minimum concentration of dopants along the line 812). In some embodiments, the second concentration of dopants 854 corresponds to a first peak in dopant concentration (e.g., a first local maximum concentration of dopants along the line 812). In some embodiments, the third concentration of dopants 856 corresponds to a second dip in dopant concentration (e.g., a second local minimum concentration of dopants along the line 812). In some embodiments, the fourth concentration of dopants 858 corresponds to a second peak in dopant concentration (e.g., a second local maximum concentration of dopants along the line 812). In some embodiments, the fifth concentration of dopants 860 corresponds to a third dip in dopant concentration (e.g., a third local minimum concentration of dopants along the line 812). In some embodiments, the first dip corresponds to at least one of a single point (corresponding to a position of the portion 810a of the diffused third doped region 801) of the dopant concentration curve of the dopant concentration data structure 850 or multiple points (e.g., a flat line) of the dopant concentration curve. In some embodiments, the first peak corresponds to at least one of a single point (corresponding to a position of the portion 810b of the diffused third doped region 801) of the dopant concentration curve of the dopant concentration data structure 850 or multiple points (e.g., a flat line) of the dopant concentration curve. In some embodiments, the second dip corresponds to at least one of a single point (corresponding to a position of the portion 810c of the diffused third doped region 801) of the dopant concentration curve of the dopant concentration data structure 850 or multiple points (e.g., a flat line) of the dopant concentration curve. In some embodiments, the second peak corresponds to at least one of a single point (corresponding to a position of the portion 810d of the diffused third doped region 801) of the dopant concentration curve of the dopant concentration data structure 850 or multiple points (e.g., a flat line) of the dopant concentration curve. In some embodiments, the third dip corresponds to at least one of a single point (corresponding to a position of the portion 810e of the diffused third doped region 801) of the dopant concentration curve of the dopant concentration data structure 850 or multiple points (e.g., a flat line) of the dopant concentration curve.

In some embodiments, each diffused portion of one, some, or all diffused portions of the first set of diffused portions has a greater concentration of dopants in an epicenter of the diffused portion than in an area outside the epicenter of the diffused portion. In some embodiments, the portion 810b corresponds to an epicenter of the diffused portion 802g. In some embodiments, the portion 810a and the portion 810c are outside the epicenter of the diffused portion 802g. In some embodiments, the second concentration of dopants 854 of the portion 810b is greater than the first concentration of dopants of the portion 810a and the third concentration of dopants of the portion 810c due, at least in part, to dopants of the diffused portion 802g being more concentrated in the epicenter of the diffused portion 802g than in other areas outside the epicenter of the diffused portion 802g. Embodiments are contemplated in which dopants are less concentrated in the epicenter of the diffused portion 802g than in areas of the diffused portion 802g that are outside the epicenter of the diffused portion 802g, such as where the second concentration of dopants 854 of the portion 810b comprising the epicenter is less than at least one of (i) the first concentration of dopants 852 of the portion 810a of the diffused portion 802g, or (ii) the third concentration of dopants 856 of the portion 810c of the diffused portion 802g. In embodiments in which dopants are less concentrated in the epicenter of the diffused portion 802g than in areas of the diffused portion 802g that are outside the epicenter of the diffused portion 802g, the dopant concentration curve of the dopant concentration data structure 850 (shown in FIG. 5F) is modified, such as shifted.

In some embodiments, the diffused third doped region 801 comprises a first sidewall 822 (shown with a dashed line curve in FIG. 8C). In some embodiments, the first sidewall 822 comprises sidewalls of some or all diffused portions of a column of diffused portions. In some embodiments, the first sidewall 822 comprises at least one of a sidewall of the diffused portion 802a, a sidewall of the diffused portion 802c, a sidewall of the diffused portion 802e, a sidewall of the diffused portion 802g, a sidewall of the diffused portion 802i, a sidewall of the diffused portion 802k, or a sidewall of the diffused portion 802m. In some embodiments, the first sidewall 822 is non-linear such that a first portion 824a of the first sidewall 822 is separated from a second portion 824b of the first sidewall 822 by a portion 826 of the semiconductor body 102. In some embodiments, dopants of the portion 826 of the semiconductor body 102 are of a different conductivity type than dopants of the diffused third doped region 801, such as where dopants of the portion 826 are n-type dopants and dopants of the diffused third doped region 801 are p-type dopants or where dopants of the portion 826 are p-type dopants and dopants of the diffused third doped region 801 are n-type dopants. Embodiments are contemplated in which dopants of the portion 826 of the semiconductor body 102 are of the same conductivity type as dopants of the diffused third doped region 801. In some embodiments, the first portion 824a of the first sidewall 822 has a first slope having a first polarity, and at least some of the second portion 824b of the first sidewall 822 has a second slope having a second polarity. In some embodiments, the first polarity is opposite the second polarity. In some embodiments, at least one of the first portion 824a of the first sidewall 822 is curved, or an entirety of the first portion 824a of the first sidewall 822 does not have the first slope. In some embodiments, at least one of the second portion 824b of the first sidewall 822 is curved, or an entirety of the second portion 824b of the first sidewall 822 does not have the second slope. In some embodiments, an angle 828 is defined between the first portion 824a of the first sidewall 822 and the second portion 824b of the first sidewall 822. In some embodiments, the angle 828 is less than 180 degrees. In some embodiments, the first portion 824a of the first sidewall 822 comprises at least some of the sidewall of the diffused portion 802e. In some embodiments, the second portion 824b of the first sidewall 822 comprises at least some of the sidewall of the diffused portion 802g.

In some embodiments, the diffused third doped region 801 comprises a second sidewall 832 (shown with a dashed line curve in FIG. 8C). In some embodiments, the second sidewall 832 comprises sidewalls of some or all diffused portions of a column of diffused portions. In some embodiments, the second sidewall 832 comprises at least one of a sidewall of the diffused portion 802b, a sidewall of the diffused portion 802d, a sidewall of the diffused portion 802f, a sidewall of the diffused portion 802h, a sidewall of the diffused portion 802j, a sidewall of the diffused portion 802l, or a sidewall of the diffused portion 802n. In some embodiments, the second sidewall 832 is non-linear such that a first portion 834a of the second sidewall 832 is separated from a second portion 834b of the second sidewall 832 by a portion 836 of the semiconductor body 102. In some embodiments, dopants of the portion 836 of the semiconductor body 102 are of a different conductivity type than dopants of the diffused third doped region 801, such as where dopants of the portion 836 are n-type dopants and dopants of the diffused third doped region 801 are p-type dopants or where dopants of the portion 836 are p-type dopants and dopants of the diffused third doped region 801 are n-type dopants. Embodiments are contemplated in which dopants of the portion 836 of the semiconductor body 102 are of the same conductivity type as dopants of the diffused third doped region 801. In some embodiments, the first portion 834a of the second sidewall 832 has a third slope having a third polarity, and at least some of the second portion 834b of the second sidewall 832 has a fourth slope having a fourth polarity. In some embodiments, the third polarity is opposite the fourth polarity. In some embodiments, at least one of the first portion 834a of the second sidewall 832 is curved, or an entirety of the first portion 834a of the second sidewall 832 does not have the third slope. In some embodiments, at least one of the second portion 834b of the second sidewall 832 is curved, or an entirety of the second portion 834b of the second sidewall 832 does not have the fourth slope. In some embodiments, an angle 838 is defined between the first portion 834a of the second sidewall 832 and the second portion 834b of the second sidewall 832. In some embodiments, the angle 838 is less than 180 degrees. In some embodiments, the first portion 834a of the second sidewall 832 comprises at least some of the sidewall of the diffused portion 802f. In some embodiments, the second portion 834b of the second sidewall 832 comprises at least some of the sidewall of the diffused portion 802h.

In some embodiments, the diffused third doped region 801 is interspersed with one or more spacing regions comprising at least one of a spacing region 840a, a spacing region 840b, a spacing region 840c, a spacing region 840d, a spacing region 840e, or a spacing region 840f. In some embodiments, dopants of each spacing region of one, some, or all of the one or more spacing regions are different than dopants of the diffused third doped region 801, such as where dopants of the one or more spacing regions are n-type dopants and dopants of the diffused third doped region 801 are p-type dopants or where dopants of the one or more spacing regions are p-type dopants and dopants of the diffused third doped region 801 are n-type dopants. In some embodiments, each spacing region of one, some, or all of the one or more spacing regions corresponds to a portion of the semiconductor body 102 (e.g., a portion, of the semiconductor body 102, that is not part of the diffused third doped region 801). In some embodiments, the spacing region 840a separates the diffused portion 802a from at least one of the diffused portion 802b or the diffused portion 802d.

In some embodiments, the transistor comprises at least one of the drain region 120 (shown in FIG. 1B), the source region 122 (shown in FIG. 1B), the channel region 124, or the gate structure. In some embodiments, a state of the transistor is controlled by a voltage applied to the gate electrode 604 of the gate structure. In some embodiments, when the transistor is in an on state, current flows through the channel region 124 between the source region 122 and the drain region 120. In some embodiments, the semiconductor device 100 comprises at least one of a drain contact (not shown) of the transistor or a source contact (not shown) of the transistor. In some embodiments, the drain contact of the transistor is connected, such as electrically connected, to the fourth doped region 110. In some embodiments, the source contact of the transistor is connected, such as electrically connected, to at least one of the sixth doped region 112 or the seventh doped region 114. In some embodiments, at least one of the source contact or the drain contact of the transistor comprises a butted contact structure.

In some embodiments, forming the semiconductor device 100 to include at least one of the third doped region 401 or the diffused third doped region 801 provides for an increase of a breakdown voltage of the transistor as compared to semiconductor devices that do not include the third doped region 401 or the diffused third doped region 801. In some embodiments, the breakdown voltage corresponds to a voltage, across the drain contact and the source contact, that causes at least some of the semiconductor device 100 to at least one of experience electrical breakdown or become electrically conductive, thus allowing current to flow between the drain contact and the source contact (even when the transistor is operated to be in the off state, for example). In some embodiments, some applications require the breakdown voltage to be greater than a threshold breakdown voltage. Implementation of the semiconductor device 100 with at least one of the third doped region 401 or the diffused third doped region 801 provides for the breakdown voltage being greater than the threshold breakdown voltage, thereby enabling the semiconductor device 100 to be used for the applications associated with the threshold breakdown voltage.

In some embodiments, forming the third doped region 401 based upon the doping map that is indicative of spaced apart portions 402a-402n of the third doped region 401 provides for at least one of (i) a reduction of an on state resistance (Ron) of the transistor, or (ii) a reduction of at least one of a device size of the semiconductor device 100, a transistor size of the transistor, a transistor pitch, etc., as compared to semiconductor devices that are generated based upon doping maps indicative of a bulk doped region. In some embodiments, reducing the on state resistance of the transistor provides for reduced power consumption of the transistor, and thus improved operating efficiency. In some embodiments, the present disclosure provides for a reduction of between about 10% to about 20% of the device size of the semiconductor device 100.

In some embodiments, the diffused third doped region 801 being interspersed with the one or more spacing regions provides for at least one of (i) a reduction of the on state resistance of the transistor, or (ii) a reduction of at least one of a device size of the semiconductor device 100, a transistor size of the transistor, a transistor pitch, etc., as compared to a semiconductor device without the one or more spacing regions.

In some embodiments, the diffused third doped region 801 having the gradient of dopant concentrations as provided for herein provides for at least one of (i) a reduction of the on state resistance of the transistor, or (ii) a reduction of at least one of a device size of the semiconductor device 100, a transistor size of the transistor, a transistor pitch, etc., as compared to a semiconductor device without the gradient of dopant concentrations.

In some embodiments, at least one of (i) dopants of the first doped region 106 are n-type dopants (e.g., the first doped region 106 is a shallow n-well (SH_N)), (ii) dopants of the second doped region 108 are p-type dopants (e.g., the second doped region 108 is a high voltage p-body (HVPB) region), (iii) dopants of the third doped region 401 and the diffused third doped region 801 are p-type dopants (e.g., at least one of the third doped region 401 or the diffused third doped region 801 is a p-type double diffusion (PDD) region), (iv) dopants of the fourth doped region 110 are n-type dopants (e.g., the fourth doped region 110 is an N+ region), (v) dopants of the fifth doped region 104 are n-type dopants (e.g., the fifth doped region 104 is a high voltage n-well (HVNW)), (vi) dopants of the sixth doped region 112 are n-type dopants (e.g., the sixth doped region is an N+ region), (vii) dopants of the seventh doped region 114 are p-type dopants (e.g., the seventh doped region 114 is a P+ region), (viii) dopants of the eighth doped region 116 are n-type dopants (e.g., the eighth doped region 116 is an n-type buried layer (NBL)), (ix) the semiconductor body 102 at least one of comprises or is over a p-type substrate, such as a substrate comprising p-type dopants, wherein the eighth doped region 116 is over at least some of the p-type substrate, or (x) the transistor is an n-type LDMOS transistor. In some embodiments, the first doped region 106 being doped with n-type dopants and the third doped region 401 being doped with p-type dopants provides for an increase of the breakdown voltage of the transistor, as compared with a semiconductor device in which the third doped region 401 and the first doped region 106 are formed with dopants of the same conductivity type.

In some embodiments, at least one of (i) dopants of the first doped region 106 are n-type dopants (e.g., the first doped region 106 is a shallow n-well (SH_N)), (ii) dopants of the second doped region 108 are p-type dopants (e.g., the second doped region 108 is a high voltage p-body (HVPB) region), (iii) dopants of the third doped region 401 and the diffused third doped region 801 are n-type dopants (e.g., at least one of the third doped region 401 or the diffused third doped region 801 is an n-type double diffusion (NDD) region), (iv) dopants of the fourth doped region 110 are n-type dopants (e.g., the fourth doped region 110 is an N+ region), (v) dopants of the fifth doped region 104 are n-type dopants (e.g., the fifth doped region 104 is a high voltage n-well (HVNW)), (vi) dopants of the sixth doped region 112 are n-type dopants (e.g., the sixth doped region is an N+ region), (vii) dopants of the seventh doped region 114 are p-type dopants (e.g., the seventh doped region 114 is a P+ region), (viii) dopants of the eighth doped region 116 are n-type dopants (e.g., the eighth doped region 116 is an n-type buried layer (NBL)), (ix) the semiconductor body 102 at least one of comprises or is over a p-type substrate, such as a substrate comprising p-type dopants, wherein the eighth doped region 116 is over at least some of the p-type substrate, or (x) the transistor is an n-type LDMOS transistor. In some embodiments, the first doped region 106 and the third doped region 401 both comprising n-type dopants provides for a reduction of the on state resistance of the transistor.

In some embodiments, at least one of (i) dopants of the first doped region 106 are p-type dopants (e.g., the first doped region 106 is a shallow p-well (SH_P)), (ii) dopants of the second doped region 108 are n-type dopants (e.g., the second doped region 108 is at least one of a shallow n-well (SH_N) or a high voltage n-body (HVNB) region), (iii) dopants of the third doped region 401 and the diffused third doped region 801 are n-type dopants (e.g., at least one of the third doped region 401 or the diffused third doped region 801 is an n-type double diffusion (NDD) region), (iv) dopants of the fourth doped region 110 are p-type dopants (e.g., the fourth doped region 110 is a P+ region), (v) dopants of the fifth doped region 104 are p-type dopants (e.g., the fifth doped region 104 is a high voltage p-well (HVPW)), (vi) dopants of the sixth doped region 112 are p-type dopants (e.g., the sixth doped region is a P+ region), (vii) dopants of the seventh doped region 114 are n-type dopants (e.g., the seventh doped region 114 is an N+ region), (viii) dopants of the eighth doped region 116 are n-type dopants (e.g., the eighth doped region 116 is an n-type buried layer (NBL)), (ix) the semiconductor body 102 at least one of comprises or is over a p-type substrate, such as a substrate comprising p-type dopants, wherein the eighth doped region 116 is over at least some of the p-type substrate, or (x) the transistor is a p-type LDMOS transistor. In some embodiments, the first doped region 106 being doped with p-type dopants and the third doped region 401 being doped with n-type dopants provides for an increase of the breakdown voltage of the transistor, as compared with a semiconductor device in which the third doped region 401 and the first doped region 106 are formed with dopants of the same conductivity type.

In some embodiments, at least one of (i) dopants of the first doped region 106 are p-type dopants (e.g., the first doped region 106 is a shallow p-well (SH_P)), (ii) dopants of the second doped region 108 are n-type dopants (e.g., the second doped region 108 is at least one of a shallow n-well (SH_N) or a high voltage n-body (HVNB) region), (iii) dopants of the third doped region 401 and the diffused third doped region 801 are p-type dopants (e.g., at least one of the third doped region 401 or the diffused third doped region 801 is a p-type double diffusion (PDD) region), (iv) dopants of the fourth doped region 110 are p-type dopants (e.g., the fourth doped region 110 is a P+ region), (v) dopants of the fifth doped region 104 are p-type dopants (e.g., the fifth doped region 104 is a high voltage p-well (HVPW)), (vi) dopants of the sixth doped region 112 are p-type dopants (e.g., the sixth doped region is a P+ region), (vii) dopants of the seventh doped region 114 are n-type dopants (e.g., the seventh doped region 114 is an N+ region), (viii) dopants of the eighth doped region 116 are n-type dopants (e.g., the eighth doped region 116 is an n-type buried layer (NBL)), (ix) the semiconductor body 102 at least one of comprises or is over a p-type substrate, such as a substrate comprising p-type dopants, wherein the eighth doped region 116 is over at least some of the p-type substrate, or (x) the transistor is a p-type LDMOS transistor. In some embodiments, the first doped region 106 and the third doped region 401 both comprising p-type dopants provides for a reduction of the on state resistance of the transistor.

In some embodiments, a method is provided. The method comprises performing one or more doping processes at least one of (i) a second doping process to form the first doped region 106, such as using one or more of the techniques provided herein with respect to forming the third doped region 401 and/or other suitable doping techniques, (ii) a third doping process to form the second doped region 108, such as using one or more of the techniques provided herein with respect to forming the third doped region 401 and/or other suitable doping techniques, (iii) the first doping process to form the third doped region 401, (iv) a fourth doping process to form the fourth doped region 110, such as using one or more of the techniques provided herein with respect to forming the third doped region 401 and/or other suitable doping techniques, (v) a fifth doping process to form the fifth doped region 104, such as using one or more of the techniques provided herein with respect to forming the third doped region 401 and/or other suitable doping techniques, (vi) a sixth doping process to form the sixth doped region 112, such as using one or more of the techniques provided herein with respect to forming the third doped region 401 and/or other suitable doping techniques, (vii) a seventh doping process to form the seventh doped region 114, such as using one or more of the techniques provided herein with respect to forming the third doped region 401 and/or other suitable doping techniques, or (viii) an eighth doping process to form the eighth doped region 116, such as using one or more of the techniques provided herein with respect to forming the third doped region 401 and/or other suitable doping techniques. In some embodiments, at least some of the one or more doping processes are performed concurrently. In some embodiments, at least some of the one or more doping processes are performed sequentially.

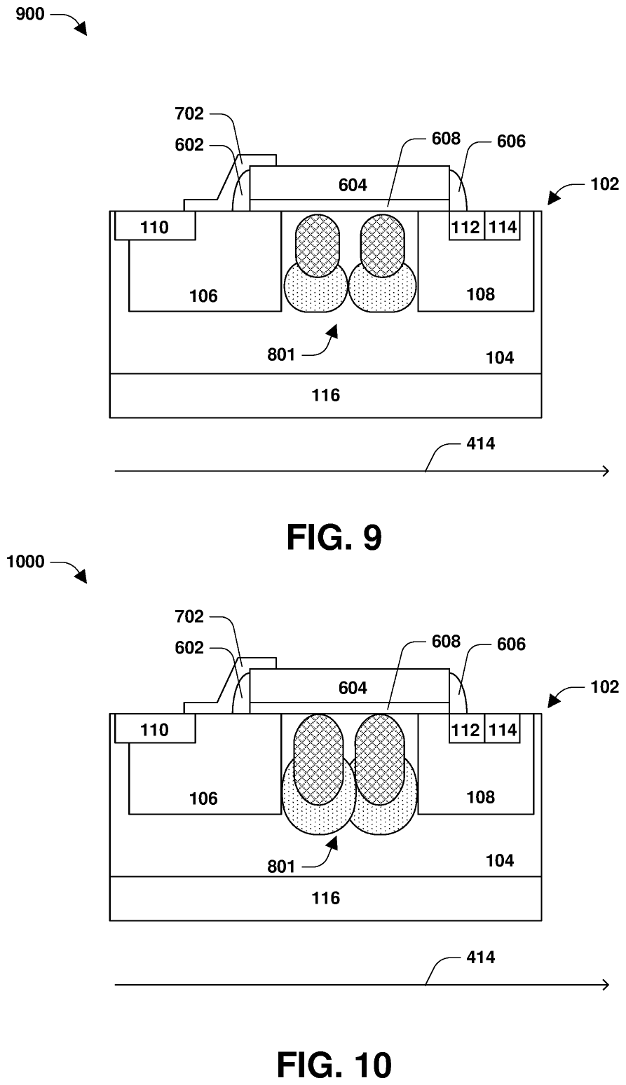

FIG. 9 illustrates a semiconductor device 900 according to some embodiments. In some embodiments, the semiconductor device 900 is formed using one or more of the techniques provided herein with respect to forming the semiconductor device 100 (shown in FIGS. 1A-8E). In some embodiments, the semiconductor device 900 includes at least some of the layers, features, elements, etc., provided herein with respect to the semiconductor device 100 and relationships between the same. In some embodiments, the semiconductor device 900 comprises the diffused third doped region 801 formed using a doping map that at least one of (i) is indicative of the height A′ being about equal to the depth A (e.g., the height A′ is about 1 micrometer and the depth A is about 1 micrometer), (ii) satisfies a design function comprising A′/(A′+A)=0.5, or (iii) is indicative of the number of columns M being equal to two.

FIG. 10 illustrates a semiconductor device 1000 according to some embodiments. In some embodiments, the semiconductor device 1000 is formed using one or more of the techniques provided herein with respect to forming the semiconductor device 100 (shown in FIGS. 1A-8E). In some embodiments, the semiconductor device 1000 includes at least some of the layers, features, elements, etc., provided herein with respect to the semiconductor device 100 and relationships between the same. In some embodiments, the semiconductor device 1000 comprises the diffused third doped region 801 formed using a doping map that at least one of (i) is indicative of the height A′ (of one, some, or all portions of the third doped region 401) being larger than the depth A (of one, some, or all portions of the third doped region 401) (e.g., the height A′ is about 1.5 micrometers and the depth A is about 0.5 micrometers), (ii) satisfies a design function comprising A′/(A′+A)=0.75, or (iii) is indicative of the number of columns M being equal to two.

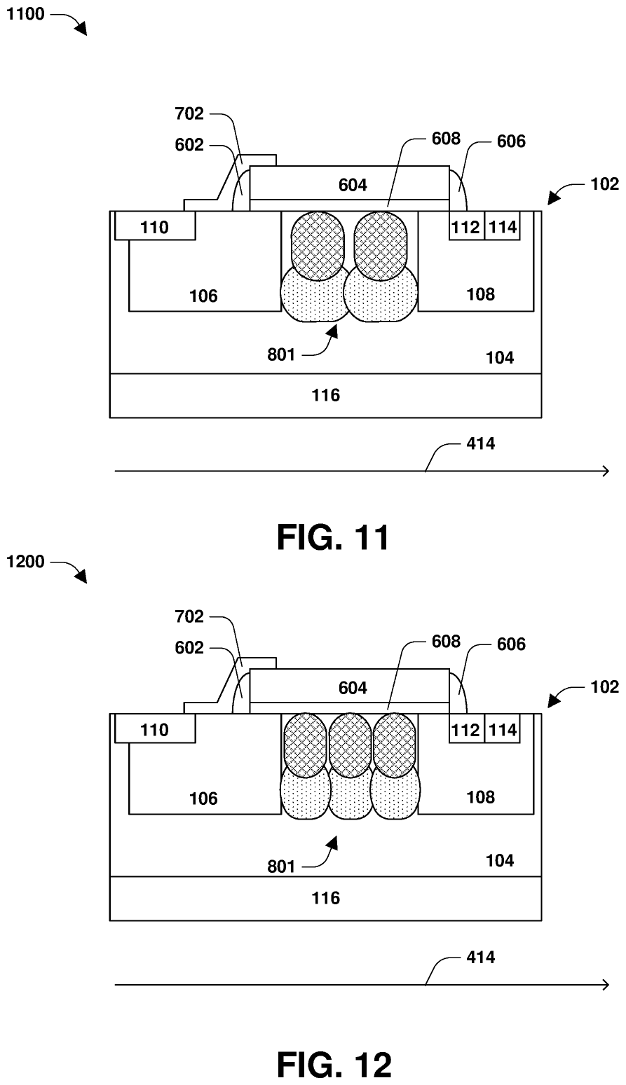

FIG. 11 illustrates a semiconductor device 1100 according to some embodiments. In some embodiments, the semiconductor device 1100 is formed using one or more of the techniques provided herein with respect to forming the semiconductor device 100 (shown in FIGS. 1A-8E). In some embodiments, the semiconductor device 1100 includes at least some of the layers, features, elements, etc., provided herein with respect to the semiconductor device 100 and relationships between the same. In some embodiments, the semiconductor device 1100 comprises the diffused third doped region 801 formed using a doping map that at least one of (i) is indicative of the length B′ (of one, some, or all portions of the third doped region 401) being the same for each column of portions of the first set of columns (e.g., the length B′ of one, some, or all portions of the third doped region 401 is about 0.5 micrometers), (ii) is indicative of the distance C (between adjacent portions in different columns of the third doped region 401) being about equal to the length B′ (e.g., the distance C is about 0.5 micrometers), (iii) is indicative of the number of columns M being equal to two, or (iv) satisfies a design function comprising M×B′/[M×B′+(M−1)×C]=0.67.

FIG. 12 illustrates a semiconductor device 1200 according to some embodiments. In some embodiments, the semiconductor device 1200 is formed using one or more of the techniques provided herein with respect to forming the semiconductor device 100 (shown in FIGS. 1A-8E). In some embodiments, the semiconductor device 1200 includes at least some of the layers, features, elements, etc., provided herein with respect to the semiconductor device 100 and relationships between the same. In some embodiments, the semiconductor device 1200 comprises the diffused third doped region 801 formed using a doping map that at least one of (i) is indicative of the length B′ (of one, some, or all portions of the third doped region 401) being about the same for each column of portions of the first set of columns (e.g., the length B′ of one, some, or all portions of the third doped region 401 is about 0.4 micrometers), (ii) is indicative of the distance C (between adjacent portions in different columns of the third doped region 401) being less than the length B′ (e.g., the distance C is about 0.15 micrometers), (iii) is indicative of the number of columns M being equal to three, or (iv) satisfies a design function comprising M×B′/[M×B′+(M−1)×C]=0.8.

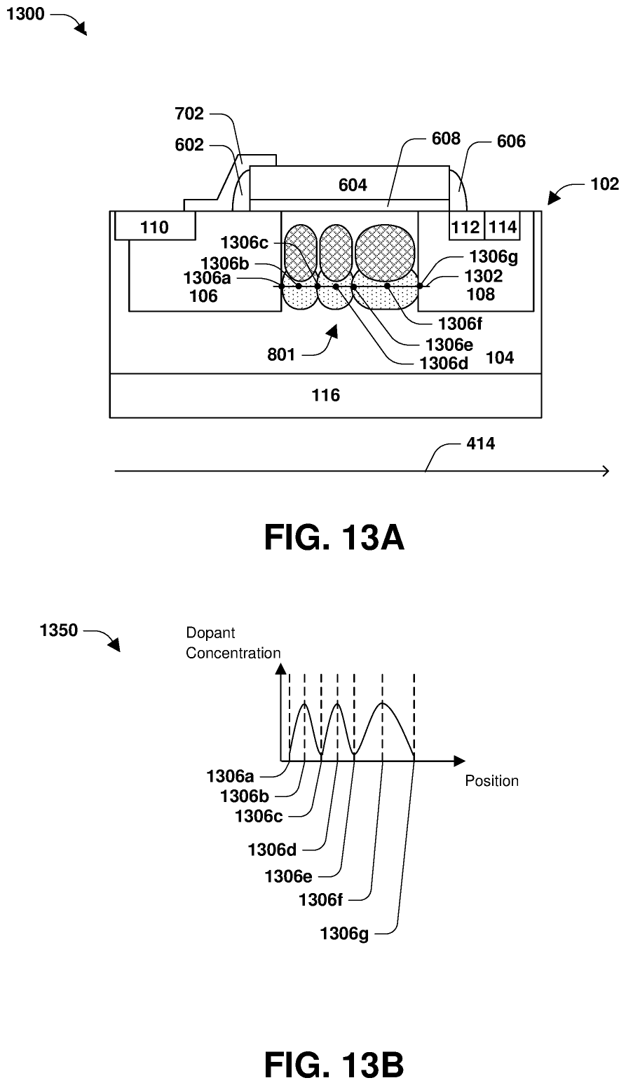

FIG. 13A illustrates a semiconductor device 1300 according to some embodiments. In some embodiments, the semiconductor device 1300 is formed using one or more of the techniques provided herein with respect to forming the semiconductor device 100 (shown in FIGS. 1A-8E). In some embodiments, the semiconductor device 1300 includes at least some of the layers, features, elements, etc., provided herein with respect to the semiconductor device 100 and relationships between the same. In some embodiments, the semiconductor device 1300 comprises the diffused third doped region 801 formed using a doping map that at least one of (i) is indicative of the number of columns M of the first set of columns being equal to three, (ii) is indicative of a first length B′1 (e.g., length of a portion along the second horizontal axis 414) of portions of a first column of the first set of columns, (iii) is indicative of a second length B′2 (e.g., length of a portion along the second horizontal axis 414) of portions of a second column of the first set of columns, (iv) is indicative of a third length B′3 (e.g., length of a portion along the second horizontal axis 414) of portions of a third column of the first set of columns, wherein the second column is between the first column and the third column, (v) is indicative of the first length B′1 being about equal to the second length B′2, (vi) is indicative of the third length B′3 being greater than the first length B′1 and the second length B′2, or (vii) is indicative of the distance C (between adjacent portions in different columns of the third doped region 401) being about the same for each column of portions of the first set of columns. FIG. 13B illustrates a dopant concentration data structure 1350 indicative of concentrations of dopants of the diffused third doped region 801 along a line 1302 through portions 1306a, 1306b, 1306c, 1306d, 1306e, 1306f, and 1306g (shown in FIG. 13A) of the diffused third doped region 801, according to some embodiments.

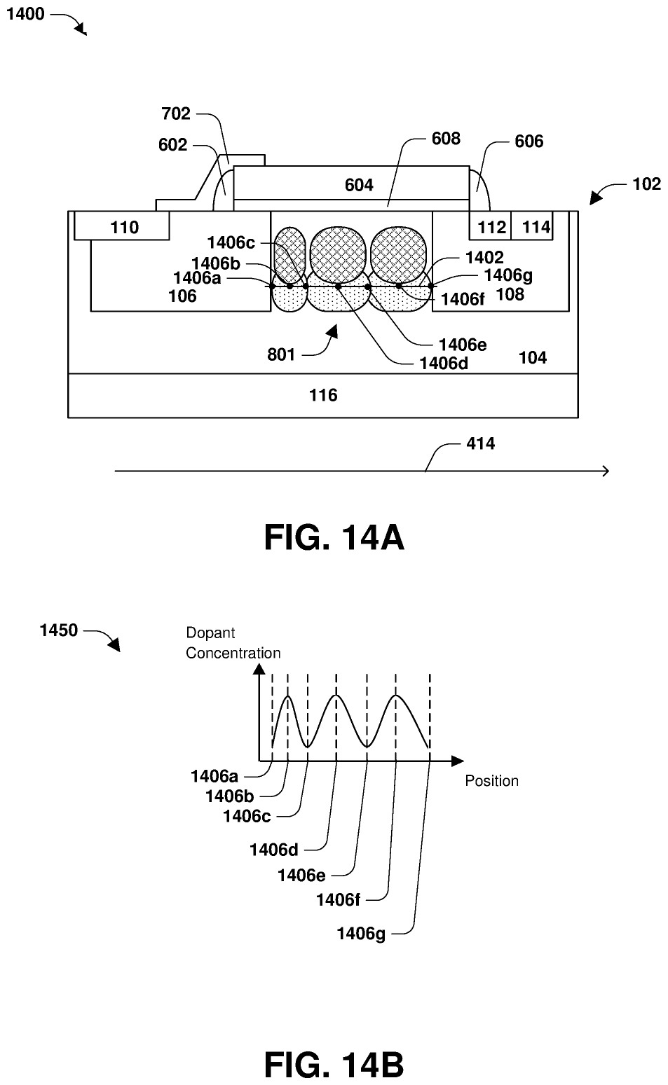

FIG. 14A illustrates a semiconductor device 1400 according to some embodiments. In some embodiments, the semiconductor device 1400 is formed using one or more of the techniques provided herein with respect to forming the semiconductor device 100 (shown in FIGS. 1A-8E). In some embodiments, the semiconductor device 1400 includes at least some of the layers, features, elements, etc., provided herein with respect to the semiconductor device 100 and relationships between the same. In some embodiments, the semiconductor device 1400 comprises the diffused third doped region 801 formed using a doping map that at least one of (i) is indicative of the number of columns M of the first set of columns being equal to three, (ii) is indicative of a first length B′1 (e.g., length of a portion along the second horizontal axis 414) of portions of a first column of the first set of columns, (iii) is indicative of a second length B′2 (e.g., length of a portion along the second horizontal axis 414) of portions of a second column of the first set of columns, (iv) is indicative of a third length B′3 (e.g., length of a portion along the second horizontal axis 414) of portions of a third column of the first set of columns, wherein the second column is between the first column and the third column, (v) is indicative of the third length B′3 being about equal to the second length B′2, (vi) is indicative of the first length B′1 being less than the second length B′2 and the third length B′3, or (vii) is indicative of the distance C (between adjacent portions in different columns of the third doped region 401) being about the same for each column of portions of the first set of columns. FIG. 14B illustrates dopant concentration data structure 1450 indicative of concentrations of dopants of the diffused third doped region 801 along a line 1402 through portions 1406a, 1406b, 1406c, 1406d, 1406e, 1406f, and 1406g (shown in FIG. 14A) of the diffused third doped region 801, according to some embodiments.

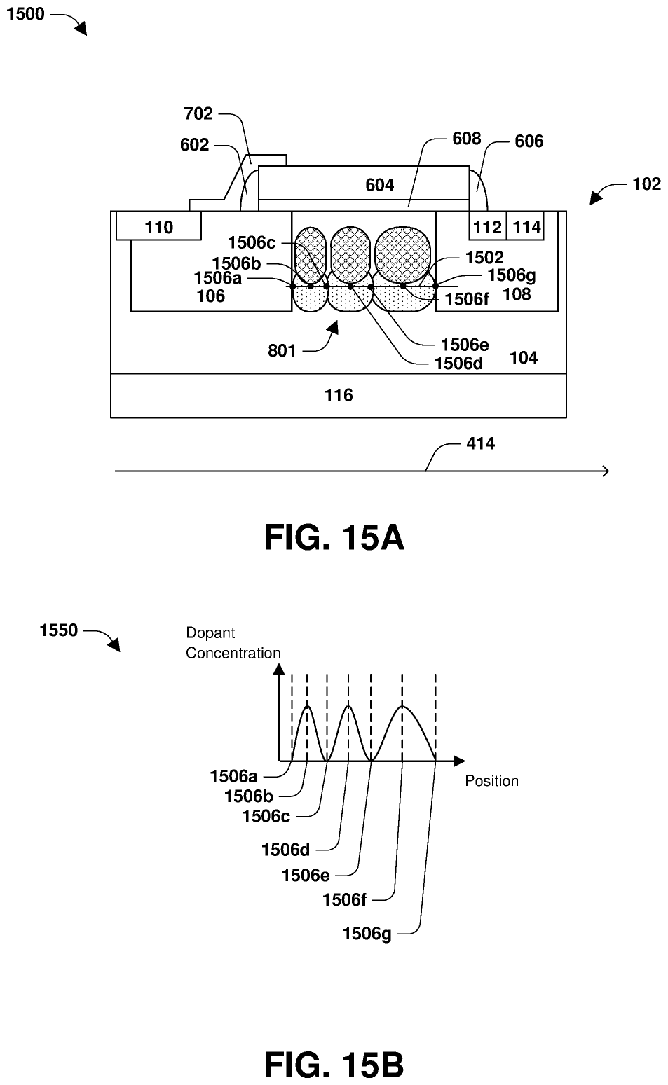

FIG. 15A illustrates a semiconductor device 1500 according to some embodiments. In some embodiments, the semiconductor device 1500 is formed using one or more of the techniques provided herein with respect to forming the semiconductor device 100 (shown in FIGS. 1A-8E). In some embodiments, the semiconductor device 1500 includes at least some of the layers, features, elements, etc., provided herein with respect to the semiconductor device 100 and relationships between the same. In some embodiments, the semiconductor device 1500 comprises the diffused third doped region 801 formed using a doping map that at least one of (i) is indicative of the number of columns M of the first set of columns being equal to three, (ii) is indicative of a first length B′1 (e.g., length of a portion along the second horizontal axis 414) of portions of a first column of the first set of columns, (iii) is indicative of a second length B′2 (e.g., length of a portion along the second horizontal axis 414) of portions of a second column of the first set of columns, (iv) is indicative of a third length B′3 (e.g., length of a portion along the second horizontal axis 414) of portions of a third column of the first set of columns, wherein the second column is between the first column and the third column, (v) is indicative of the first length B′1 being less than the second length B′2, (vi) is indicative of the second length B′2 being less than the third length B′3, or (vii) is indicative of the distance C (between adjacent portions in different columns of the third doped region 401) being about the same for each column of portions of the first set of columns. FIG. 15B illustrates dopant concentration data structure 1550 indicative of concentrations of dopants of the diffused third doped region 801 along a line 1502 through portions 1506a, 1506b, 1506c, 1506d, 1506e, 1506f, and 1506g (shown in FIG. 15A) of the diffused third doped region 801, according to some embodiments.

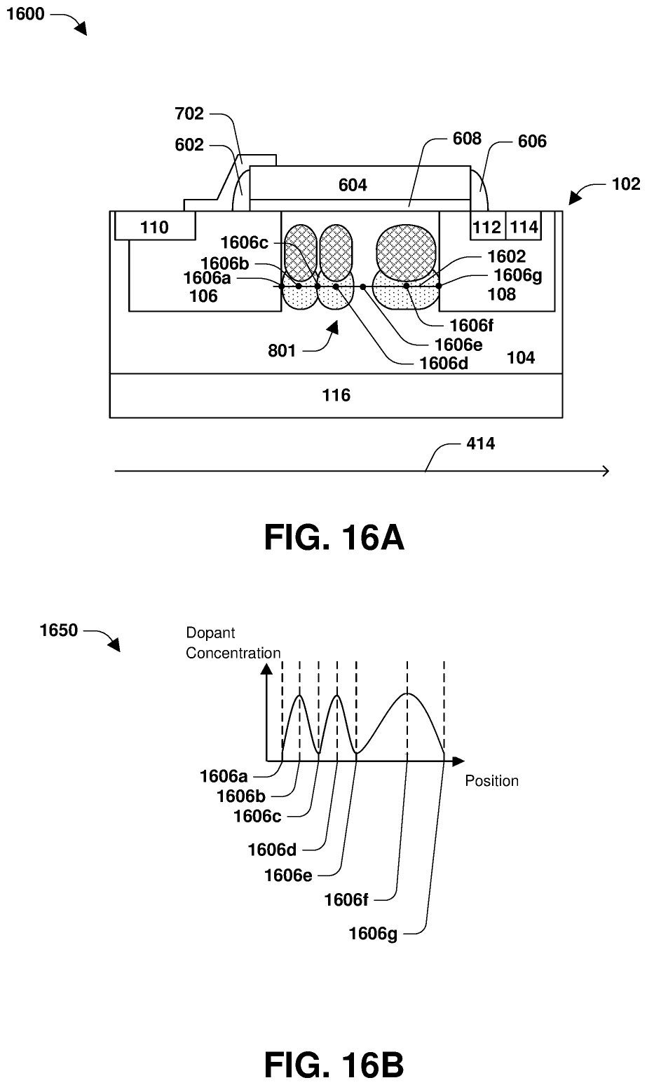

FIG. 16A illustrates a semiconductor device 1600 according to some embodiments. In some embodiments, the semiconductor device 1600 is formed using one or more of the techniques provided herein with respect to forming the semiconductor device 100 (shown in FIGS. 1A-8E). In some embodiments, the semiconductor device 1600 includes at least some of the layers, features, elements, etc., provided herein with respect to the semiconductor device 100 and relationships between the same. In some embodiments, the semiconductor device 1600 comprises the diffused third doped region 801 formed using a doping map that at least one of (i) is indicative of the number of columns M of the first set of columns being equal to three, (ii) is indicative of a first length B′1 (e.g., length of a portion along the second horizontal axis 414) of portions of a first column of the first set of columns, (iii) is indicative of a second length B′2 (e.g., length of a portion along the second horizontal axis 414) of portions of a second column of the first set of columns, (iv) is indicative of a third length B′3 (e.g., length of a portion along the second horizontal axis 414) of portions of a third column of the first set of columns, wherein the second column is between the first column and the third column, (v) the first length B′1 being about equal to the second length B′2, (vi) is indicative of the third length B′3 being greater than the first length B′1 and the second length B′2, or (vii) is indicative of a first distance C1 being less than a second distance C2, wherein the first distance C1 corresponds to a distance between a portion in the first column and an adjacent portion in the second column, and/or the second distance C2 corresponds to a distance between a portion in the second column and an adjacent portion in the third column. FIG. 16B illustrates a dopant concentration data structure 1650 indicative of concentrations of dopants of the diffused third doped region 801 along a line 1602 through portions 1606a, 1606b, 1606c, 1606d, 1606e, 1606f, and 1606g (shown in FIG. 16A) of the diffused third doped region 801, according to some embodiments.

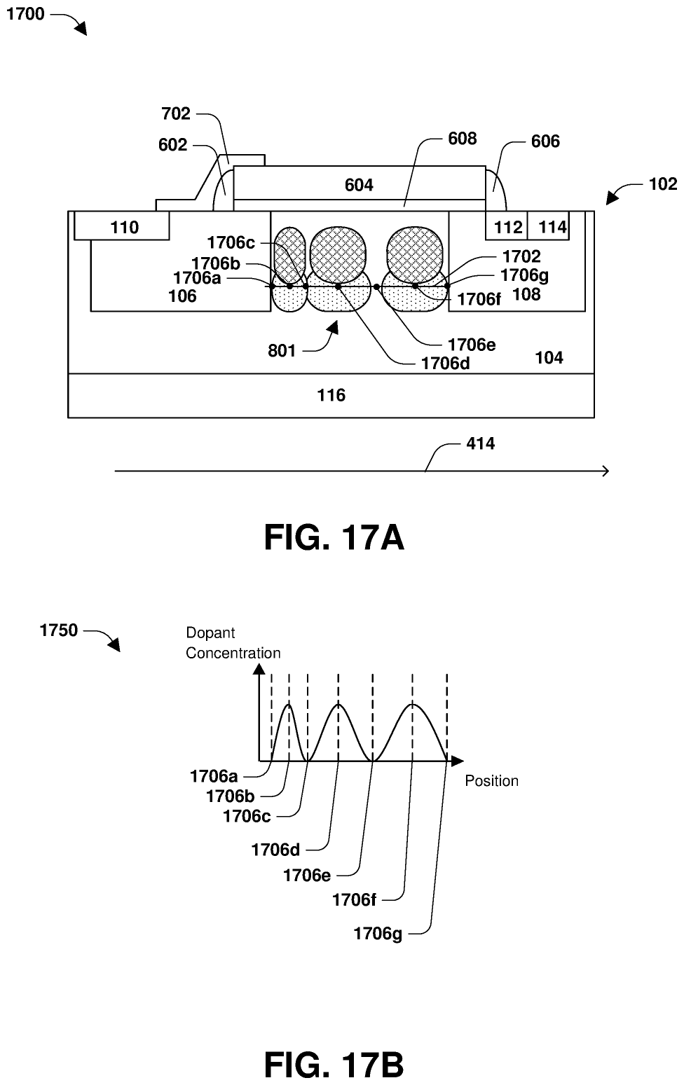

FIG. 17A illustrates a semiconductor device 1700 according to some embodiments. In some embodiments, the semiconductor device 1700 is formed using one or more of the techniques provided herein with respect to forming the semiconductor device 100 (shown in FIGS. 1A-8E). In some embodiments, the semiconductor device 1700 includes at least some of the layers, features, elements, etc., provided herein with respect to the semiconductor device 100 and relationships between the same. In some embodiments, the semiconductor device 1700 comprises the diffused third doped region 801 formed using a doping map that at least one of (i) is indicative of the number of columns M of the first set of columns being equal to three, (ii) is indicative of a first length B′1 (e.g., length of a portion along the second horizontal axis 414) of portions of a first column of the first set of columns, (iii) is indicative of a second length B′2 (e.g., length of a portion along the second horizontal axis 414) of portions of a second column of the first set of columns, (iv) is indicative of a third length B′3 (e.g., length of a portion along the second horizontal axis 414) of portions of a third column of the first set of columns, wherein the second column is between the first column and the third column, (v) is indicative of the third length B′3 being about equal to the second length B′2, (vi) is indicative of the first length B′1 being less than the second length B′2 and the third length B′3, or (vii) is indicative of a first distance C1 being less than a second distance C2, wherein the first distance C1 corresponds to a distance between a portion in the first column and an adjacent portion in the second column, and/or the second distance C2 corresponds to a distance between a portion in the second column and an adjacent portion in the third column. FIG. 17B illustrates dopant concentration data structure 1750 indicative of concentrations of dopants of the diffused third doped region 801 along a line 1702 through portions 1706a, 1706b, 1706c, 1706d, 1706e, 1706f, and 1706g (shown in FIG. 17A) of the diffused third doped region 801, according to some embodiments.

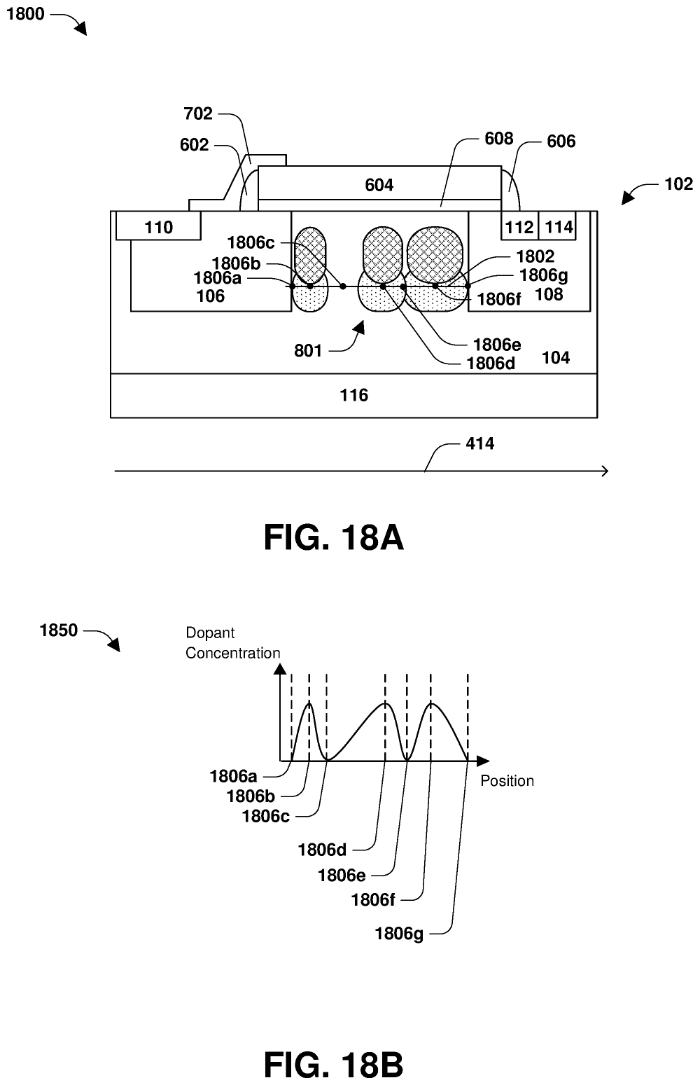

FIG. 18A illustrates a semiconductor device 1800 according to some embodiments. In some embodiments, the semiconductor device 1800 is formed using one or more of the techniques provided herein with respect to forming the semiconductor device 100 (shown in FIGS. 1A-8E). In some embodiments, the semiconductor device 1800 includes at least some of the layers, features, elements, etc., provided herein with respect to the semiconductor device 100 and relationships between the same. In some embodiments, the semiconductor device 1800 comprises the diffused third doped region 801 formed using a doping map that at least one of (i) is indicative of the number of columns M of the first set of columns being equal to three, (ii) is indicative of a first length B′1 (e.g., length of a portion along the second horizontal axis 414) of portions of a first column of the first set of columns, (iii) is indicative of a second length B′2 (e.g., length of a portion along the second horizontal axis 414) of portions of a second column of the first set of columns, (iv) is indicative of a third length B′3 (e.g., length of a portion along the second horizontal axis 414) of portions of a third column of the first set of columns, wherein the second column is between the first column and the third column, (v) is indicative of the first length B′1 being less than the second length B′2, (vi) is indicative of the second length B′2 being less than the third length B′3, or (vii) is indicative of a first distance C1 being greater than a second distance C2, wherein the first distance C1 corresponds to a distance between a portion in the first column and an adjacent portion in the second column, and/or the second distance C2 corresponds to a distance between a portion in the second column and an adjacent portion in the third column. FIG. 18B illustrates dopant concentration data structure 1850 indicative of concentrations of dopants of the diffused third doped region 801 along a line 1802 through portions 1806a, 1806b, 1806c, 1806d, 1806e, 1806f, and 1806g (shown in FIG. 18A) of the diffused third doped region 801, according to some embodiments.

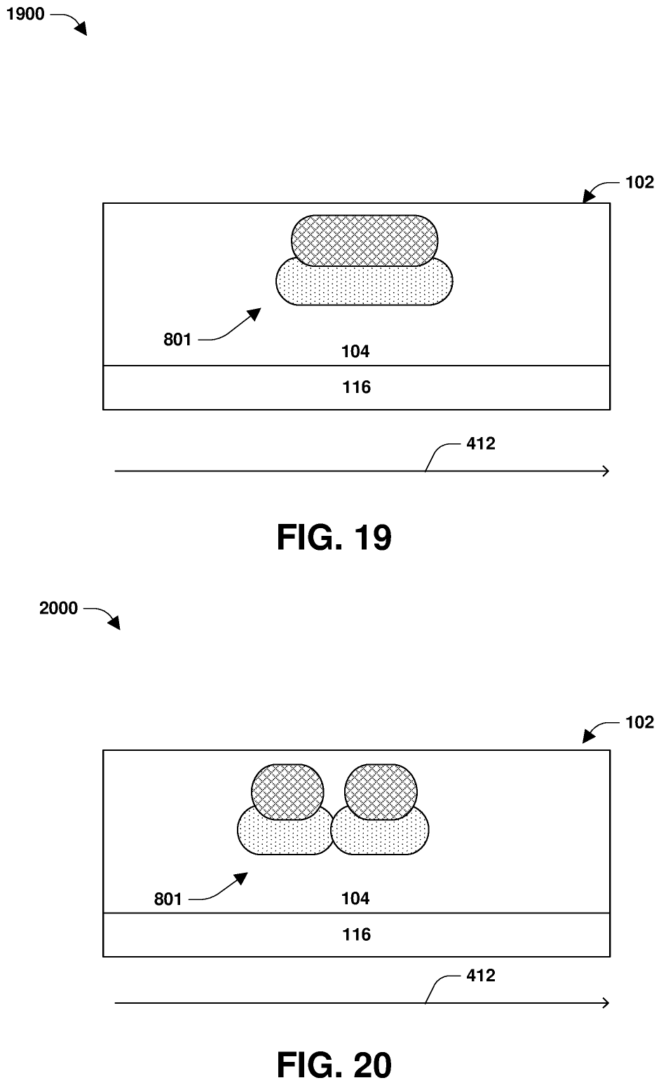

FIG. 19 illustrates a semiconductor device 1900 according to some embodiments. In some embodiments, the semiconductor device 1900 is formed using one or more of the techniques provided herein with respect to forming the semiconductor device 100 (shown in FIGS. 1A-8E). In some embodiments, the semiconductor device 1900 includes at least some of the layers, features, elements, etc., provided herein with respect to the semiconductor device 100 and relationships between the same. In some embodiments, the semiconductor device 1900 comprises the diffused third doped region 801 formed using a doping map that at least one of (i) is indicative of the number of rows N along the first horizontal axis 412 being equal to one, (ii) is indicative of the width D′ (of one, some, or all portions of the third doped region 401) being about 1.5 micrometers, or (iii) satisfies a design function comprising N×D′/[N×D′+(N−1)×E]=1.

FIG. 20 illustrates a semiconductor device 2000 according to some embodiments. In some embodiments, the semiconductor device 2000 is formed using one or more of the techniques provided herein with respect to forming the semiconductor device 100 (shown in FIGS. 1A-8E). In some embodiments, the semiconductor device 2000 includes at least some of the layers, features, elements, etc., provided herein with respect to the semiconductor device 100 and relationships between the same. In some embodiments, the semiconductor device 2000 comprises the diffused third doped region 801 formed using a doping map that at least one of (i) is indicative of the number of rows N along the first horizontal axis 412 being equal to two, (ii) is indicative of the width D′ (of one, some, or all portions of the third doped region 401) being about 0.5 micrometers (e.g., the width D′ of portions is about the same for portions of a first row and portions of a second row), (iii) is indicative of the distance E (between adjacent portions in different rows of the third doped region 401) being about the same for each row of portions of the first set of rows (e.g., the distance E is about 0.5 micrometers), or (iv) satisfies a design function comprising N×D′/[N×D′+(N−1)×E]=0.67.

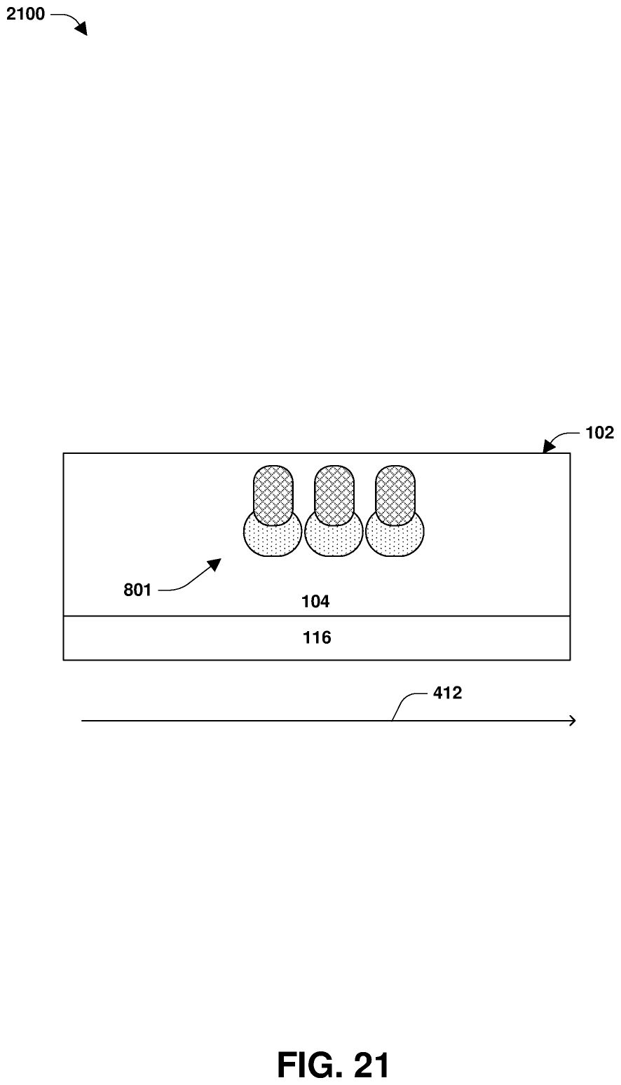

FIG. 21 illustrates a semiconductor device 2100 according to some embodiments. In some embodiments, the semiconductor device 2100 is formed using one or more of the techniques provided herein with respect to forming the semiconductor device 100 (shown in FIGS. 1A-8E). In some embodiments, the semiconductor device 2100 includes at least some of the layers, features, elements, etc., provided herein with respect to the semiconductor device 100 and relationships between the same. In some embodiments, the semiconductor device 2100 comprises the diffused third doped region 801 formed using a doping map that at least one of (i) is indicative of the number of rows N along the first horizontal axis 412 being equal to three, (ii) is indicative of the width D′ (of one, some, or all portions of the third doped region 401) being about 0.4 micrometers (e.g., the width D′ of portions is about the same for portions of a first row, portions of a second row and portions of a third row), (iii) is indicative of the distance E (between adjacent portions in different rows of the third doped region 401) being about the same for each row of portions of the first set of rows (e.g., the distance E is about 0.15 micrometers), or (iv) satisfies a design function comprising N×D′/[N×D′+(N−1)×E]=0.8.

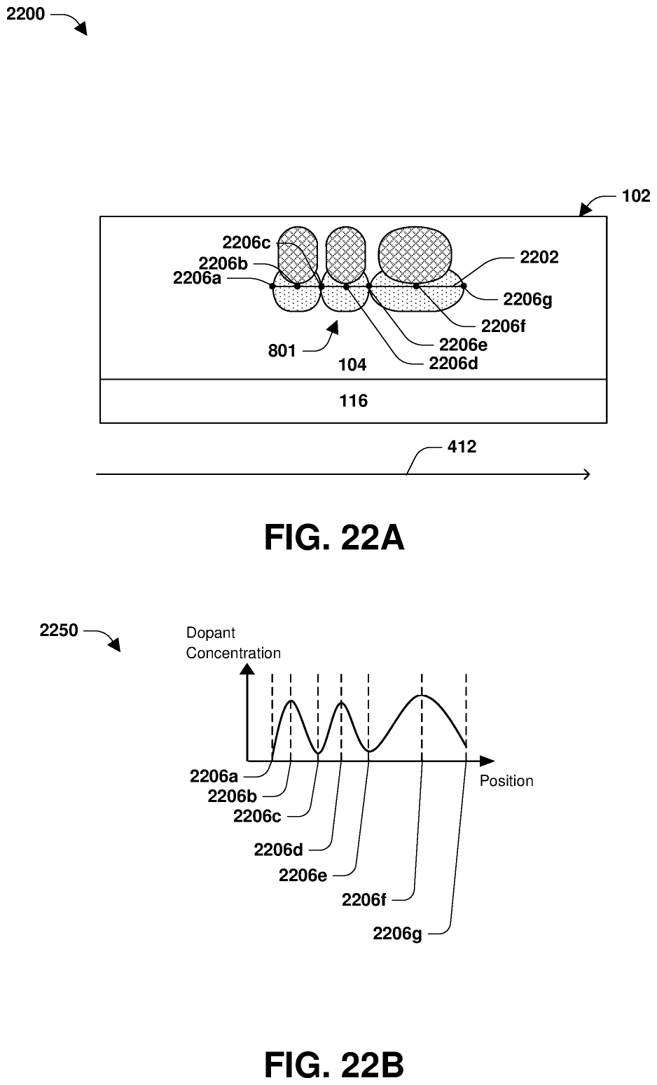

FIG. 22A illustrates a semiconductor device 2200 according to some embodiments. In some embodiments, the semiconductor device 2200 is formed using one or more of the techniques provided herein with respect to forming the semiconductor device 100 (shown in FIGS. 1A-8E). In some embodiments, the semiconductor device 2200 includes at least some of the layers, features, elements, etc., provided herein with respect to the semiconductor device 100 and relationships between the same. In some embodiments, the semiconductor device 2200 comprises the diffused third doped region 801 formed using a doping map that at least one of (i) is indicative of the number of rows N of the first set of rows along the first horizontal axis 412 being equal to three, (ii) is indicative of a first width D′1 (e.g., length of a portion along the first horizontal axis 412) of portions of a first row of the first set of rows, (iii) is indicative of a second width D′2 (e.g., length of a portion along the first horizontal axis 412) of portions of a second row of the first set of rows, (iv) is indicative of a third width D′3 (e.g., length of a portion along the first horizontal axis 412) of portions of a third row of the first set of rows, wherein the second rows is between the first rows and the third rows, (v) is indicative of the first width D′1 being about equal to the second width D′2, (vi) is indicative of the third width D′3 being greater than the first width D′1 and the second width D′2, or (vii) is indicative of the distance E (between adjacent portions in different rows of the third doped region 401) being about the same for each row of portions of the first set of rows. FIG. 22B illustrates a dopant concentration data structure 2250 indicative of concentrations of dopants of the diffused third doped region 801 along a line 2202 through portions 2206a, 2206b, 2206c, 2206d, 2206e, 2206f, and 2206g (shown in FIG. 22A) of the diffused third doped region 801, according to some embodiments.

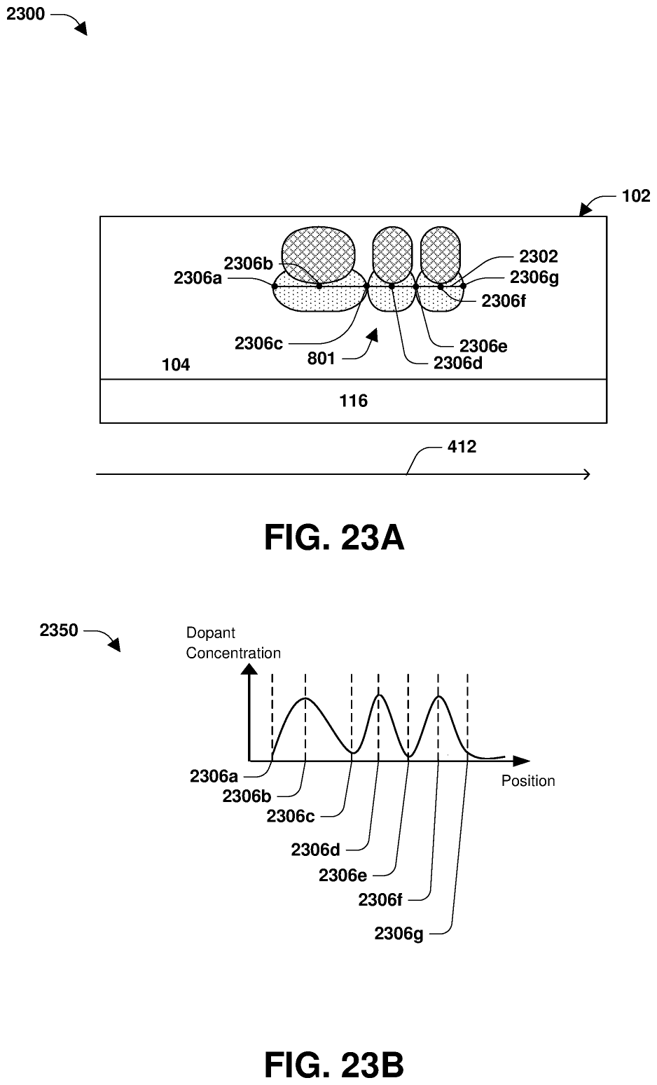

FIG. 23A illustrates a semiconductor device 2300 according to some embodiments. In some embodiments, the semiconductor device 2300 is formed using one or more of the techniques provided herein with respect to forming the semiconductor device 100 (shown in FIGS. 1A-8E). In some embodiments, the semiconductor device 2300 includes at least some of the layers, features, elements, etc., provided herein with respect to the semiconductor device 100 and relationships between the same. In some embodiments, the semiconductor device 2300 comprises the diffused third doped region 801 formed using a doping map that at least one of (i) is indicative of the number of rows N of the first set of rows along the first horizontal axis 412 being equal to three, (ii) is indicative of a first width D′1 (e.g., length of a portion along the first horizontal axis 412) of portions of a first row of the first set of rows, (iii) is indicative of a second width D′2 (e.g., length of a portion along the first horizontal axis 412) of portions of a second row of the first set of rows, (iv) is indicative of a third width D′3 (e.g., length of a portion along the first horizontal axis 412) of portions of a third row of the first set of rows, wherein the second rows is between the first rows and the third rows, (v) is indicative of the first width D′1 being greater than the second width D′2, (vi) is indicative of the third width D′3 being about equal to the second width D′2, or (vii) is indicative of the distance E (between adjacent portions in different rows of the third doped region 401) being about the same for each row of portions of the first set of rows. FIG. 23B illustrates a dopant concentration data structure 2350 indicative of concentrations of dopants of the diffused third doped region 801 along a line 2302 through portions 2306a, 2306b, 2306c, 2306d, 2306e, 2306f, and 2306g (shown in FIG. 23A) of the diffused third doped region 801, according to some embodiments.

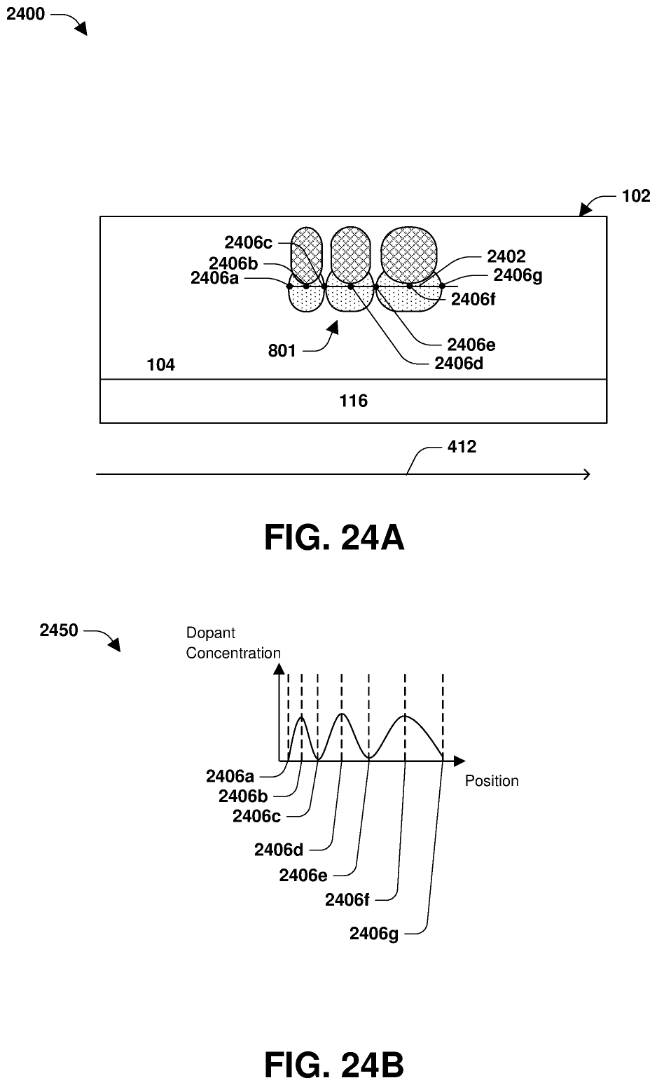

FIG. 24A illustrates a semiconductor device 2400 according to some embodiments. In some embodiments, the semiconductor device 2400 is formed using one or more of the techniques provided herein with respect to forming the semiconductor device 100 (shown in FIGS. 1A-8E). In some embodiments, the semiconductor device 2400 includes at least some of the layers, features, elements, etc., provided herein with respect to the semiconductor device 100 and relationships between the same. In some embodiments, the semiconductor device 2400 comprises the diffused third doped region 801 formed using a doping map that at least one of (i) is indicative of the number of rows N of the first set of rows along the first horizontal axis 412 being equal to three, (ii) is indicative of a first width D′1 (e.g., length of a portion along the first horizontal axis 412) of portions of a first row of the first set of rows, (iii) is indicative of a second width D′2 (e.g., length of a portion along the first horizontal axis 412) of portions of a second row of the first set of rows, (iv) is indicative of a third width D′3 (e.g., length of a portion along the first horizontal axis 412) of portions of a third row of the first set of rows, wherein the second rows is between the first rows and the third rows, (v) is indicative of the first width D′1 being less than the second width D′2, (vi) is indicative of the third width D′3 being greater than the second width D′2, or (vii) is indicative of the distance E (between adjacent portions in different rows of the third doped region 401) being about the same for each row of portions of the first set of rows. FIG. 24B illustrates a dopant concentration data structure 2450 indicative of concentrations of dopants of the diffused third doped region 801 along a line 2402 through portions 2406a, 2406b, 2406c, 2406d, 2406e, 2406f, and 2406g (shown in FIG. 24A) of the diffused third doped region 801, according to some embodiments.

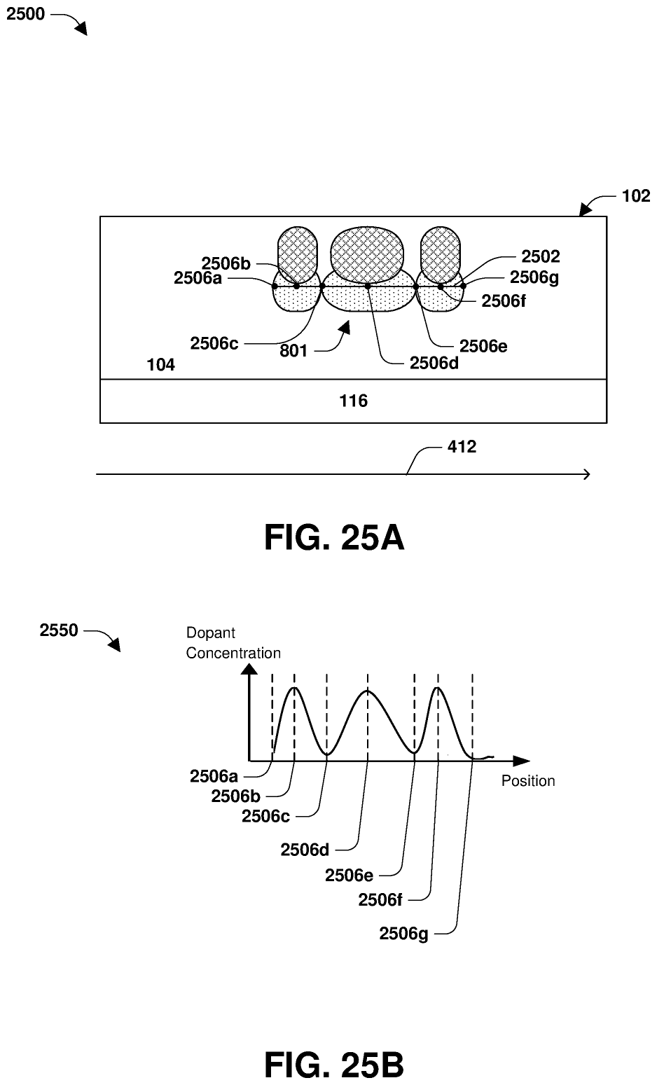

FIG. 25A illustrates a semiconductor device 2500 according to some embodiments. In some embodiments, the semiconductor device 2500 is formed using one or more of the techniques provided herein with respect to forming the semiconductor device 100 (shown in FIGS. 1A-8E). In some embodiments, the semiconductor device 2500 includes at least some of the layers, features, elements, etc., provided herein with respect to the semiconductor device 100 and relationships between the same. In some embodiments, the semiconductor device 2500 comprises the diffused third doped region 801 formed using a doping map that at least one of (i) is indicative of the number of rows N of the first set of rows along the first horizontal axis 412 being equal to three, (ii) is indicative of a first width D′1 (e.g., length of a portion along the first horizontal axis 412) of portions of a first row of the first set of rows, (iii) is indicative of a second width D′2 (e.g., length of a portion along the first horizontal axis 412) of portions of a second row of the first set of rows, (iv) is indicative of a third width D′3 (e.g., length of a portion along the first horizontal axis 412) of portions of a third row of the first set of rows, wherein the second rows is between the first rows and the third rows, (v) is indicative of the first width D′1 being about equal to the third width D′3, (vi) is indicative of the third width D′3 being less than the second width D′2, or (vii) is indicative of the distance E (between adjacent portions in different rows of the third doped region 401) being about the same for each row of portions of the first set of rows. FIG. 25B illustrates a dopant concentration data structure 2550 indicative of concentrations of dopants of the diffused third doped region 801 along a line 2502 through portions 2506a, 2506b, 2506c, 2506d, 2506e, 2506f, and 2506g (shown in FIG. 25A) of the diffused third doped region 801, according to some embodiments.

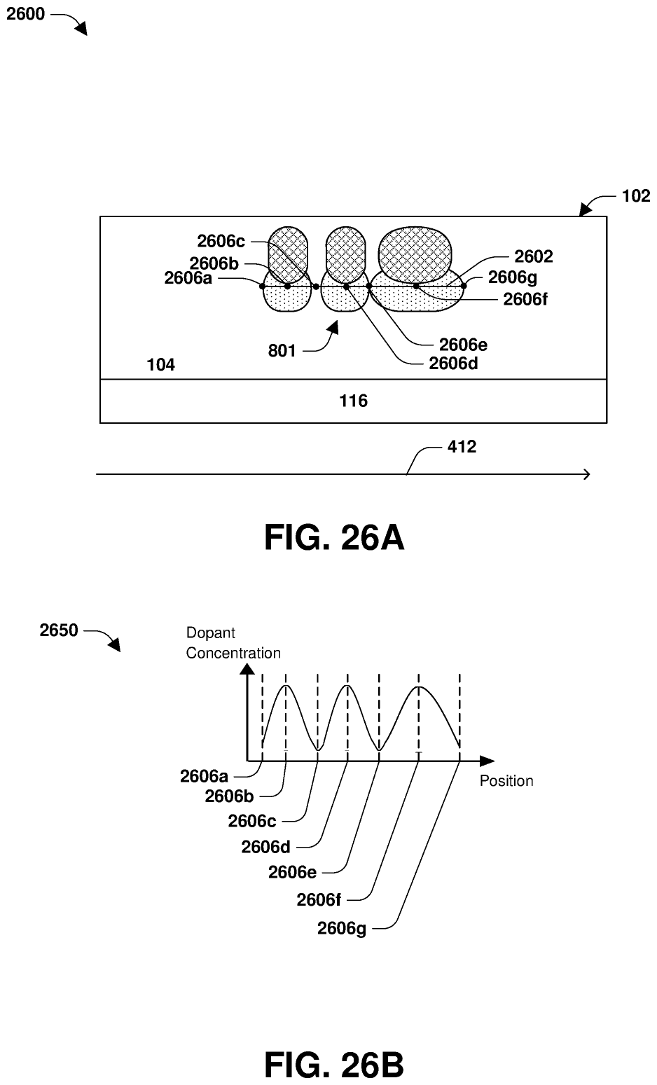

FIG. 26A illustrates a semiconductor device 2600 according to some embodiments. In some embodiments, the semiconductor device 2600 is formed using one or more of the techniques provided herein with respect to forming the semiconductor device 100 (shown in FIGS. 1A-8E). In some embodiments, the semiconductor device 2600 includes at least some of the layers, features, elements, etc., provided herein with respect to the semiconductor device 100 and relationships between the same. In some embodiments, the semiconductor device 2600 comprises the diffused third doped region 801 formed using a doping map that at least one of (i) is indicative of the number of rows N of the first set of rows along the first horizontal axis 412 being equal to three, (ii) is indicative of a first width D′1 (e.g., length of a portion along the first horizontal axis 412) of portions of a first row of the first set of rows, (iii) is indicative of a second width D′2 (e.g., length of a portion along the first horizontal axis 412) of portions of a second row of the first set of rows, (iv) is indicative of a third width D′3 (e.g., length of a portion along the first horizontal axis 412) of portions of a third row of the first set of rows, wherein the second rows is between the first rows and the third rows, (v) is indicative of the first width D′1 being about equal to the second width D′2, (vi) is indicative of the third width D′3 being greater than the first width D′1 and the second width D′2, or (vii) is indicative of a first distance E1 being greater than a second distance E2, wherein the first distance E1 corresponds to a distance between a portion in the first row and an adjacent portion in the second row, and/or the second distance E2 corresponds to a distance between a portion in the second row and an adjacent portion in the third row. FIG. 26B illustrates a dopant concentration data structure 2650 indicative of concentrations of dopants of the diffused third doped region 801 along a line 2602 through portions 2606a, 2606b, 2606c, 2606d, 2606e, 2606f, and 2606g (shown in FIG. 26A) of the diffused third doped region 801, according to some embodiments.

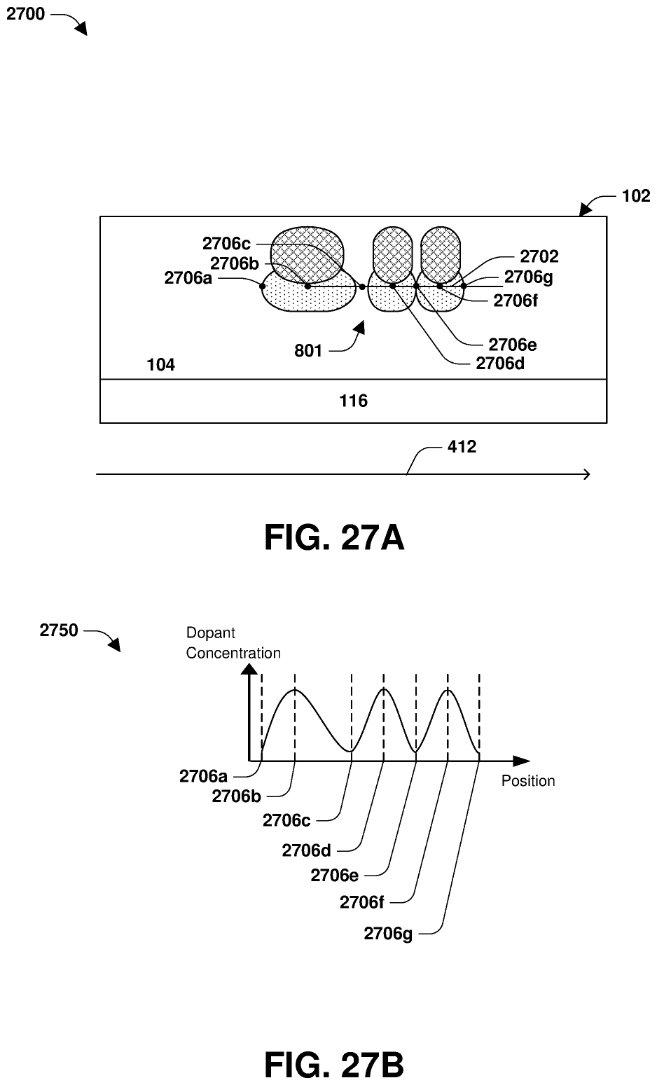

FIG. 27A illustrates a semiconductor device 2700 according to some embodiments. In some embodiments, the semiconductor device 2700 is formed using one or more of the techniques provided herein with respect to forming the semiconductor device 100 (shown in FIGS. 1A-8E). In some embodiments, the semiconductor device 2700 includes at least some of the layers, features, elements, etc., provided herein with respect to the semiconductor device 100 and relationships between the same. In some embodiments, the semiconductor device 2700 comprises the diffused third doped region 801 formed using a doping map that at least one of (i) is indicative of the number of rows N of the first set of rows along the first horizontal axis 412 being equal to three, (ii) is indicative of a first width D′1 (e.g., length of a portion along the first horizontal axis 412) of portions of a first row of the first set of rows, (iii) is indicative of a second width D′2 (e.g., length of a portion along the first horizontal axis 412) of portions of a second row of the first set of rows, (iv) is indicative of a third width D′3 (e.g., length of a portion along the first horizontal axis 412) of portions of a third row of the first set of rows, wherein the second rows is between the first rows and the third rows, (v) is indicative of the first width D′1 being greater than the second width D′2, (vi) is indicative of the third width D′3 being about equal to the second width D′2, or (vii) is indicative of a first distance E1 being greater than a second distance E2, wherein the first distance E1 corresponds to a distance between a portion in the first row and an adjacent portion in the second row, and/or the second distance E2 corresponds to a distance between a portion in the second row and an adjacent portion in the third row. FIG. 27B illustrates a dopant concentration data structure 2750 indicative of concentrations of dopants of the diffused third doped region 801 along a line 2702 through portions 2706a, 2706b, 2706c, 2706d, 2706e, 2706f, and 2706g (shown in FIG. 27A) of the diffused third doped region 801, according to some embodiments.

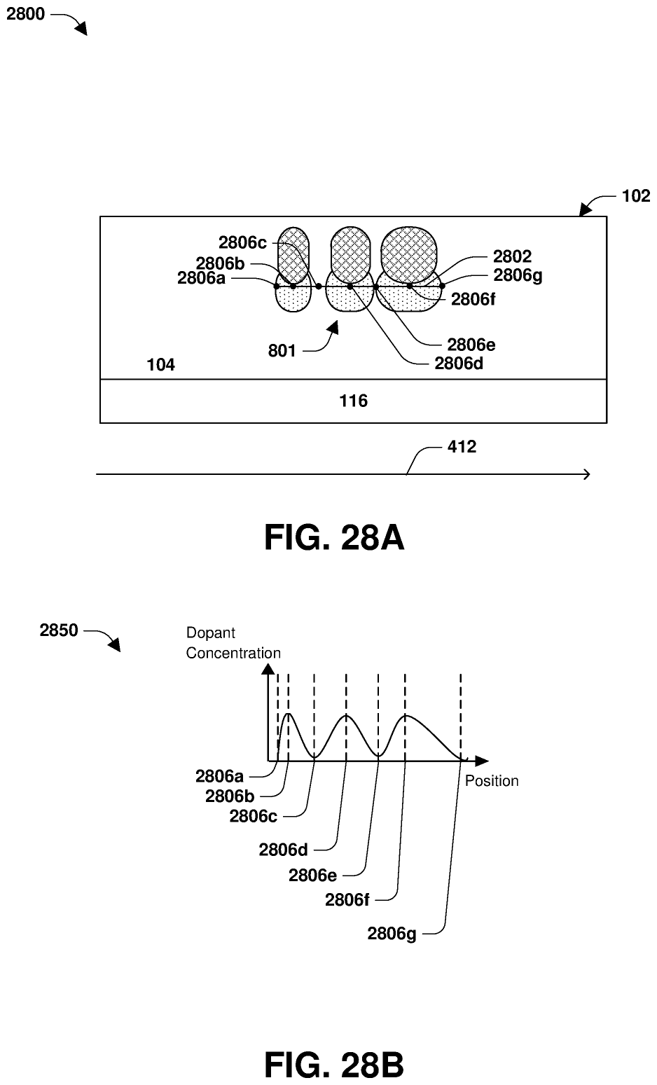

FIG. 28A illustrates a semiconductor device 2800 according to some embodiments. In some embodiments, the semiconductor device 2800 is formed using one or more of the techniques provided herein with respect to forming the semiconductor device 100 (shown in FIGS. 1A-8E). In some embodiments, the semiconductor device 2800 includes at least some of the layers, features, elements, etc., provided herein with respect to the semiconductor device 100 and relationships between the same. In some embodiments, the semiconductor device 2800 comprises the diffused third doped region 801 formed using a doping map that at least one of (i) is indicative of the number of rows N of the first set of rows along the first horizontal axis 412 being equal to three, (ii) is indicative of a first width D′1 (e.g., length of a portion along the first horizontal axis 412) of portions of a first row of the first set of rows, (iii) is indicative of a second width D′2 (e.g., length of a portion along the first horizontal axis 412) of portions of a second row of the first set of rows, (iv) is indicative of a third width D′3 (e.g., length of a portion along the first horizontal axis 412) of portions of a third row of the first set of rows, wherein the second rows is between the first rows and the third rows, (v) is indicative of the first width D′1 being less than the second width D′2, (vi) is indicative of the third width D′3 being greater than the second width D′2, or (vii) is indicative of a first distance E1 being greater than a second distance E2, wherein the first distance E1 corresponds to a distance between a portion in the first row and an adjacent portion in the second row, and/or the second distance E2 corresponds to a distance between a portion in the second row and an adjacent portion in the third row. FIG. 28B illustrates a dopant concentration data structure 2850 indicative of concentrations of dopants of the diffused third doped region 801 along a line 2802 through portions 2806a, 2806b, 2806c, 2806d, 2806e, 2806f, and 2806g (shown in FIG. 28A) of the diffused third doped region 801, according to some embodiments.

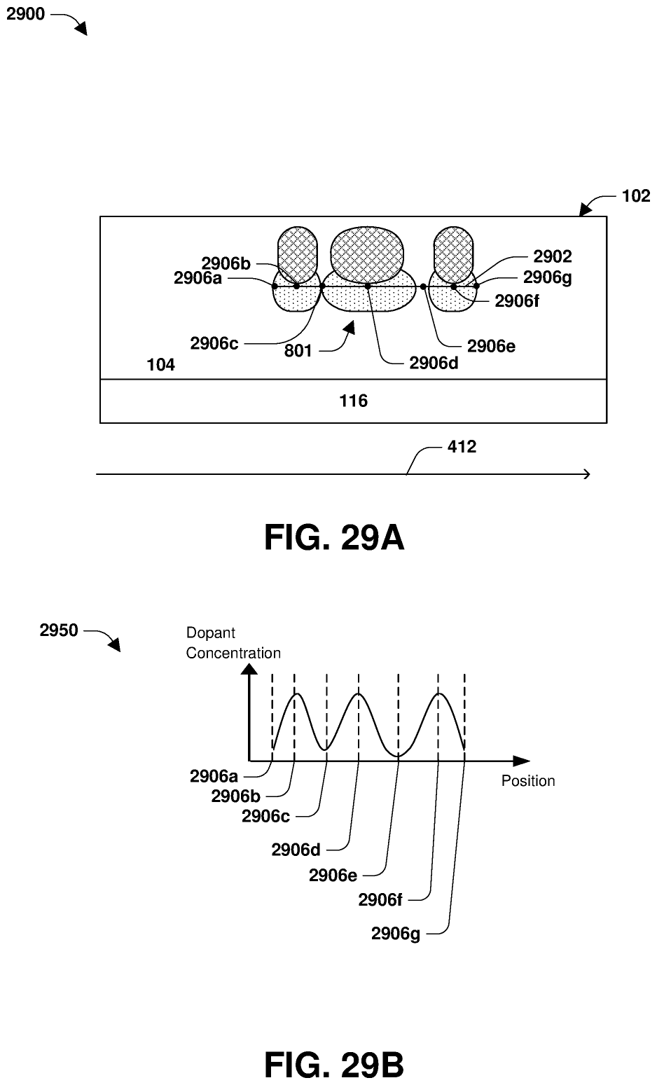

FIG. 29A illustrates a semiconductor device 2900 according to some embodiments. In some embodiments, the semiconductor device 2900 is formed using one or more of the techniques provided herein with respect to forming the semiconductor device 100 (shown in FIGS. 1A-8E). In some embodiments, the semiconductor device 2900 includes at least some of the layers, features, elements, etc., provided herein with respect to the semiconductor device 100 and relationships between the same. In some embodiments, the semiconductor device 2900 comprises the diffused third doped region 801 formed using a doping map that at least one of (i) is indicative of the number of rows N of the first set of rows along the first horizontal axis 412 being equal to three, (ii) is indicative of a first width D′1 (e.g., length of a portion along the first horizontal axis 412) of portions of a first row of the first set of rows, (iii) is indicative of a second width D′2 (e.g., length of a portion along the first horizontal axis 412) of portions of a second row of the first set of rows, (iv) is indicative of a third width D′3 (e.g., length of a portion along the first horizontal axis 412) of portions of a third row of the first set of rows, wherein the second rows is between the first rows and the third rows, (v) is indicative of the first width D′1 being about equal to the third width D′3, (vi) is indicative of the third width D′3 being less than the second width D′2, or (vii) is indicative of a first distance E1 being less than a second distance E2, wherein the first distance E1 corresponds to a distance between a portion in the first row and an adjacent portion in the second row, and/or the second distance E2 corresponds to a distance between a portion in the second row and an adjacent portion in the third row. FIG. 29B illustrates a dopant concentration data structure 2950 indicative of concentrations of dopants of the diffused third doped region 801 along a line 2902 through portions 2906a, 2906b, 2906c, 2906d, 2906e, 2906f, and 2906g (shown in FIG. 29A) of the diffused third doped region 801, according to some embodiments.

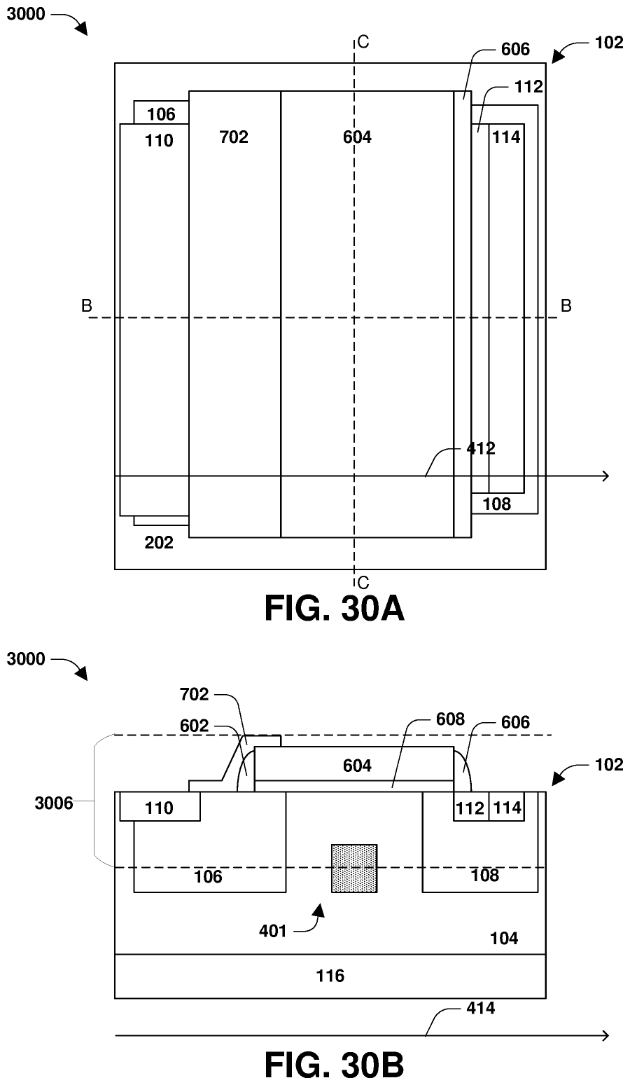

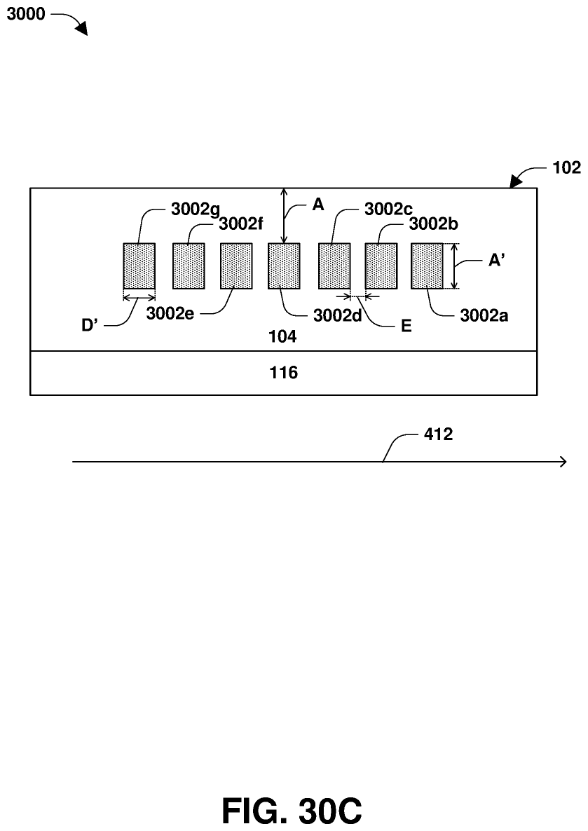

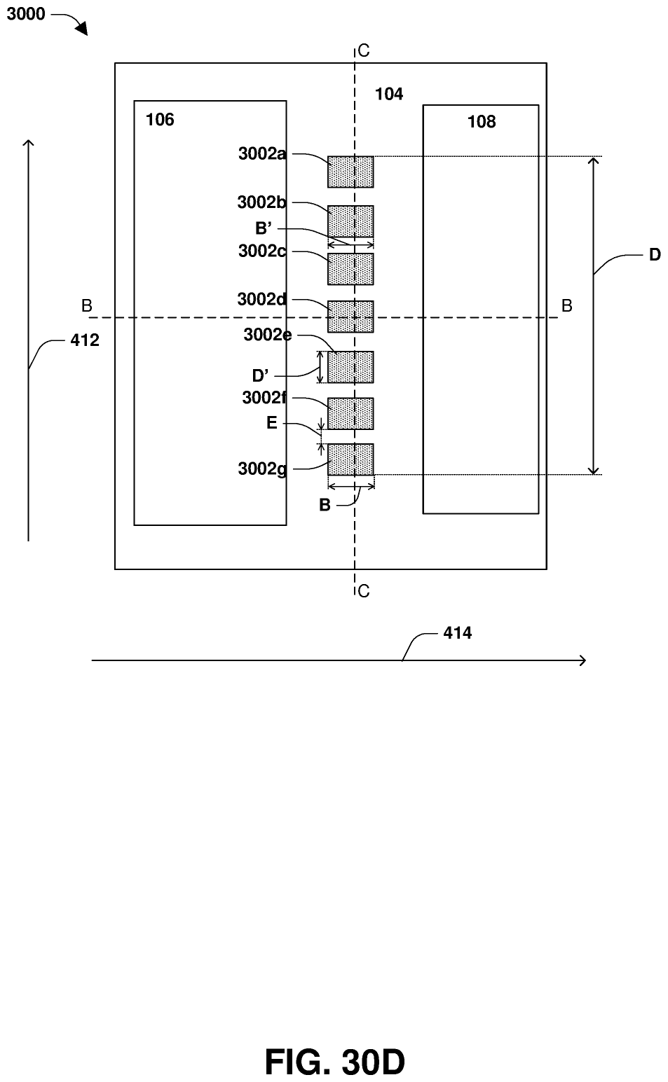

FIGS. 30A-30D illustrate a semiconductor device 3000 according to some embodiments. FIG. 30A illustrates a top view of the semiconductor device 3000. FIG. 30B illustrates a cross-sectional view of the semiconductor device 3000 taken along line B-B of FIG. 30A. FIG. 30C illustrates a cross-sectional view of the semiconductor device 3000 taken along lines C-C of FIG. 30A. FIG. 30D illustrates a top view of the semiconductor device 3000 without a top portion 3006 (shown in FIG. 30B) of the semiconductor device 3000 to show portions 3002a-3002g of the third doped region 401, in accordance with some embodiments. In some embodiments, the semiconductor device 3000 is formed using one or more of the techniques provided herein with respect to forming the semiconductor device 100 (shown in FIGS. 1A-8E). In some embodiments, the semiconductor device 3000 includes at least some of the layers, features, elements, etc., provided herein with respect to the semiconductor device 100 and relationships between the same. In some embodiments, the number of columns M is equal to one (e.g., the first set of columns of the third doped region 401 comprises merely a single column).

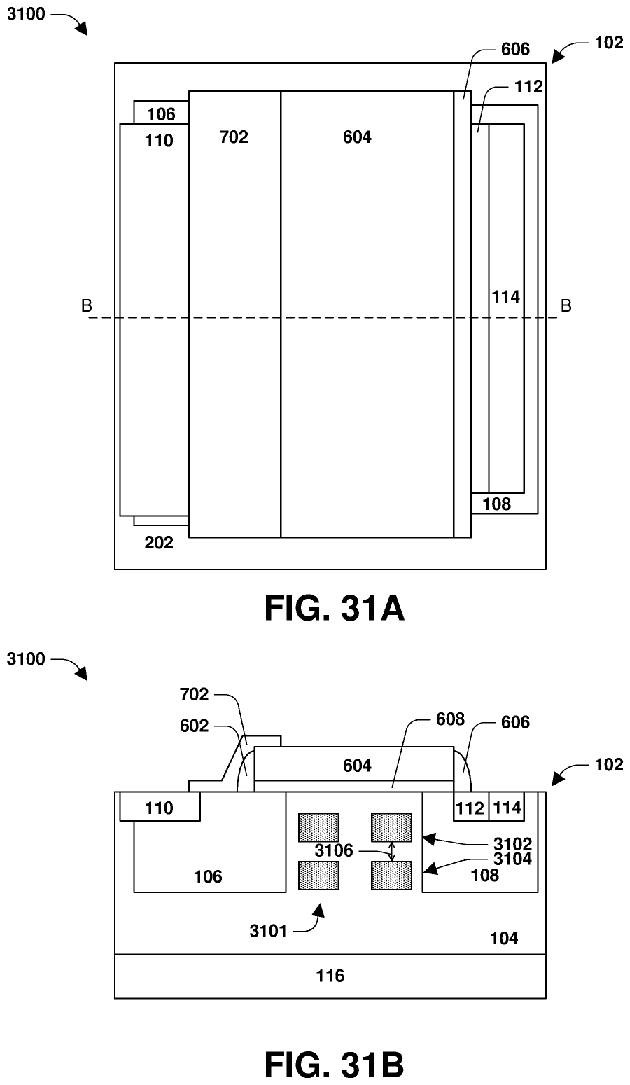

FIGS. 31A and 31B illustrate a semiconductor device 3100 according to some embodiments. FIG. 31A illustrates a top view of the semiconductor device 3100. FIG. 31B illustrates a cross-sectional view of the semiconductor device 3100 taken along line B-B of FIG. 31A. In some embodiments, the semiconductor device 3100 is formed using one or more of the techniques provided herein with respect to forming the semiconductor device 100 (shown in FIGS. 1A-8E). In some embodiments, the semiconductor device 3100 includes at least some of the layers, features, elements, etc., provided herein with respect to the semiconductor device 100 and relationships between the same. In some embodiments, the semiconductor device 3100 comprises a multi-layer third doped region 3101 comprising at least one of (i) a first layer 3102 of portions of the multi-layer third doped region 3101, (ii) a second layer 3104 of portions of the multi-layer third doped region 3101, or (iii) one or more other layers of portions of the multi-layer third doped region 3101. In some embodiments, each layer of the multi-layer third doped region 3101 comprises a matrix arrangement of the first set of rows and the first set of columns. In some embodiments, the first layer 3102 is formed using one or more of the techniques provided herein with respect to forming the third doped region 401. In some embodiments, the first layer 3102 includes at least some of the features, elements, etc., provided herein with respect to the third doped region 401 and relationships between the same. In some embodiments, the second layer 3104 is formed using one or more of the techniques provided herein with respect to forming the third doped region 401. In some embodiments, the second layer 3104 includes at least some of the features, elements, etc., provided herein with respect to the third doped region 401 and relationships between the same. In some embodiments, each portion of one, some, or all portions of the multi-layer third doped region 3101 in the first layer 3102 overlies a portion of the multi-layer third doped region 3101 in the second layer 3104. In some embodiments, the first layer 3102 is spaced apart from the second layer 3104 by about a distance 3106. In some embodiments, each portion of one, some, or all portions of the multi-layer third doped region 3101 in the first layer 3102 is spaced apart from an underlying portion of the multi-layer third doped region 3101 in the second layer 3104 by about the distance 3106. In some embodiments, dopants of the first layer 3102 are of the same conductivity type as dopants of the second layer 3104. Embodiments are contemplated in which dopants of the first layer 3102 are of a different conductivity type than dopants of the second layer 3104.

In some embodiments, the term “concentration of dopants”, as used in the present disclosure, pertains to a measure of dopants, such as at least one of a quantity of dopants per unit of area, a quantity of dopants per unit of volume, or one or more other metrics pertaining to dopants.

In some embodiments, a semiconductor device is provided. The semiconductor device includes a semiconductor body and a transistor. The transistor includes a drain region in the semiconductor body, a first doped region in the drain region, a source region in the semiconductor body, a second doped region adjacent the source region, and a third doped region between the first doped region and the second doped region. The third doped region includes a first portion having a first concentration of dopants, a second portion adjacent the first portion and having a second concentration of dopants, a third portion adjacent the second portion and having a third concentration of dopants, and a fourth portion adjacent the third portion and having a fourth concentration of dopants. The third doped region has a gradient such that, along a first line extending through the first portion, the second portion, the third portion, and the fourth portion: the first concentration is less than the second concentration, the second concentration is greater than the third concentration, and the third concentration is less than the fourth concentration.

In some embodiments, a first distance between the first portion and the second portion is less than a second distance between the first portion and the fourth portion.

In some embodiments, the first doped region includes a shallow well and the second doped region includes a high voltage body region.

In some embodiments, the transistor includes a gate structure overlying the third doped region.

In some embodiments, dopants of the first doped region are of a first conductivity type and dopants of the third doped region are of the first conductivity type.

In some embodiments, the third doped region is in the drain region.

In some embodiments, dopants of the first doped region are of a first conductivity type, dopants of the second doped region are of a second conductivity type different than the first conductivity type, and dopants of the third doped region are of the second conductivity type.

In some embodiments, the semiconductor device includes a fourth doped region, between a fifth portion of the third doped region and a sixth portion of the third doped region, and having dopants of a first conductivity type, wherein dopants of the third doped region are of a second conductivity type different than the first conductivity type.

In some embodiments, a method of forming a semiconductor device is provided. The method includes forming a first doped region in a semiconductor body, wherein the first doped region is in a drain region of a transistor. The method includes forming a second doped region in the semiconductor body, wherein the second doped region is adjacent a source region of the transistor. The method includes forming a first portion of a third doped region in the semiconductor body between the first doped region and the second doped region. The method includes forming a second portion of the third doped region in the semiconductor body between the first doped region and the second doped region. A portion of the semiconductor body separates the first portion from the second portion. Dopants of the portion of the semiconductor body are of a first conductivity type. Dopants of the third doped region are of a second conductivity type different than the first conductivity type.

In some embodiments, forming the first portion of the third doped region and forming the second portion of the third doped region includes concurrently implanting a first distribution of dopants of the second conductivity type into a first locale of the semiconductor body to form the first portion of the third doped region, and a second distribution of dopants of the second conductivity type into a second locale of the semiconductor body to form the second portion of the third doped region.

In some embodiments, forming the first portion of the third doped region and forming the second portion of the third doped region includes sequentially implanting a first distribution of dopants of the second conductivity type into a first locale of the semiconductor body to form the first portion of the third doped region, and a second distribution of dopants of the second conductivity type into a second locale of the semiconductor body to form the second portion of the third doped region.

In some embodiments, forming the first portion of the third doped region includes implanting a first distribution of dopants of the second conductivity type into a first locale of the drain region of the transistor, and forming the second portion of the third doped region includes implanting a second distribution of dopants of the second conductivity type into a second locale of the drain region of the transistor.

In some embodiments, the method includes forming a gate structure, of the transistor, over the semiconductor body, wherein the gate structure overlies the first portion of the third doped region and the second portion of the third doped region.

In some embodiments, a semiconductor device is provided. The semiconductor device includes a semiconductor body and a transistor. The transistor includes a drain region in the semiconductor body, a first doped region in the drain region, a source region in the semiconductor body, and a second doped region adjacent the source region, and a third doped region between the first doped region and the second doped region. The third doped region has a sidewall that is non-linear such that a first portion of the sidewall is separated from a second portion of the sidewall by a portion of the semiconductor body.

In some embodiments, an angle is defined between the first portion of the sidewall and the second portion of the sidewall, and at least one of the first portion of the sidewall or the second portion of the sidewall is curved.

In some embodiments, the third doped region includes a third portion having a first concentration of dopants, a fourth portion adjacent the third portion and having a second concentration of dopants, a fifth portion adjacent the fourth portion and having a third concentration of dopants, and a sixth portion adjacent the fifth portion and having a fourth concentration of dopants, wherein the third doped region has a gradient such that, along a first line extending through the third portion, the fourth portion, the fifth portion, and the sixth portion: the first concentration is less than the second concentration, the second concentration is greater than the third concentration, and the third concentration is less than the fourth concentration.

In some embodiments, the semiconductor device includes a fourth doped region, between a third portion of the third doped region and a fourth portion of the third doped region, and having dopants of a first conductivity type, wherein dopants of the third doped region are of a second conductivity type different than the first conductivity type.

In some embodiments, dopants of the first doped region are of a first conductivity type and dopants of the third doped region are of the first conductivity type.

In some embodiments, the third doped region has a second sidewall that is non-linear such that a first portion of the second sidewall is separated from a second portion of the second sidewall by a second portion of the semiconductor body.

In some embodiments, the semiconductor body has dopants of a first conductivity type, and dopants of the third doped region are of a second conductivity type different than the first conductivity type.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming the layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” and/or the like is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally to be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A semiconductor device, comprising:
a semiconductor body; and
a transistor comprising:
a drain region in the semiconductor body;
a first doped region in the drain region;
a source region in the semiconductor body;
a second doped region adjacent the source region; and
a third doped region, between the first doped region and the second doped region, comprising a first portion having a first concentration of dopants, a second portion adjacent the first portion and having a second concentration of dopants, a third portion adjacent the second portion and having a third concentration of dopants, and a fourth portion adjacent the third portion and having a fourth concentration of dopants, wherein the third doped region has a gradient such that, along a first line extending through the first portion, the second portion, the third portion, and the fourth portion:
the first concentration is less than the second concentration;
the second concentration is greater than the third concentration; and
the third concentration is less than the fourth concentration.

2. The semiconductor device of claim 1, wherein:
a first distance between the first portion and the second portion is less than a second distance between the first portion and the fourth portion.

3. The semiconductor device of claim 1, wherein:
the first doped region comprises a shallow well; and
the second doped region comprises a high voltage body region.

4. The semiconductor device of claim 1, wherein the transistor comprises:
a gate structure overlying the third doped region.

5. The semiconductor device of claim 1, wherein:
dopants of the first doped region are of a first conductivity type; and
dopants of the third doped region are of the first conductivity type.

6. The semiconductor device of claim 1, wherein:
the third doped region is in the drain region.

7. The semiconductor device of claim 1, wherein:
dopants of the first doped region are of a first conductivity type;
dopants of the second doped region are of a second conductivity type different than the first conductivity type; and
dopants of the third doped region are of the second conductivity type.

8. The semiconductor device of claim 1, comprising:
a fourth doped region, between a fifth portion of the third doped region and a sixth portion of the third doped region, and having dopants of a first conductivity type, wherein dopants of the third doped region are of a second conductivity type different than the first conductivity type.

9. A method of forming a semiconductor device, comprising:
forming a first doped region in a semiconductor body, wherein the first doped region is in a drain region of a transistor;
forming a second doped region in the semiconductor body, wherein the second doped region is adjacent a source region of the transistor;
forming a first portion of a third doped region in the semiconductor body between the first doped region and the second doped region; and
forming a second portion of the third doped region in the semiconductor body between the first doped region and the second doped region, wherein:
a portion of the semiconductor body separates the first portion from the second portion;
dopants of the portion of the semiconductor body are of a first conductivity type; and
dopants of the third doped region are of a second conductivity type different than the first conductivity type.

10. The method of claim 9, wherein forming the first portion of the third doped region and forming the second portion of the third doped region comprise:
concurrently implanting:
a first distribution of dopants of the second conductivity type into a first locale of the semiconductor body to form the first portion of the third doped region, and
a second distribution of dopants of the second conductivity type into a second locale of the semiconductor body to form the second portion of the third doped region.

11. The method of claim 9, wherein forming the first portion of the third doped region and forming the second portion of the third doped region comprise:
sequentially implanting:
a first distribution of dopants of the second conductivity type into a first locale of the semiconductor body to form the first portion of the third doped region, and
a second distribution of dopants of the second conductivity type into a second locale of the semiconductor body to form the second portion of the third doped region.

12. The method of claim 9, wherein:
forming the first portion of the third doped region comprises implanting a first distribution of dopants of the second conductivity type into a first locale of the drain region of the transistor; and
forming the second portion of the third doped region comprises implanting a second distribution of dopants of the second conductivity type into a second locale of the drain region of the transistor.

13. The method of claim 9, comprising:
forming a gate structure, of the transistor, over the semiconductor body, wherein the gate structure overlies the first portion of the third doped region and the second portion of the third doped region.

14. A semiconductor device, comprising:
a semiconductor body; and
a transistor comprising:
a drain region in the semiconductor body;
a first doped region in the drain region;
a source region in the semiconductor body;
a second doped region adjacent the source region; and
a third doped region between the first doped region and the second doped region, wherein the third doped region has a sidewall that is non-linear such that a first portion of the sidewall is separated from a second portion of the sidewall by a portion of the semiconductor body.

15. The semiconductor device of claim 14, wherein:
an angle is defined between the first portion of the sidewall and the second portion of the sidewall; and
at least one of the first portion of the sidewall or the second portion of the sidewall is curved.

16. The semiconductor device of claim 14, wherein:
the third doped region comprises a third portion having a first concentration of dopants, a fourth portion adjacent the third portion and having a second concentration of dopants, a fifth portion adjacent the fourth portion and having a third concentration of dopants, and a sixth portion adjacent the fifth portion and having a fourth concentration of dopants, wherein the third doped region has a gradient such that, along a first line extending through the third portion, the fourth portion, the fifth portion, and the sixth portion:
the first concentration is less than the second concentration;
the second concentration is greater than the third concentration; and
the third concentration is less than the fourth concentration.

17. The semiconductor device of claim 14, comprising:
a fourth doped region, between a third portion of the third doped region and a fourth portion of the third doped region, and having dopants of a first conductivity type, wherein dopants of the third doped region are of a second conductivity type different than the first conductivity type.

18. The semiconductor device of claim 14, wherein:
dopants of the first doped region are of a first conductivity type; and
dopants of the third doped region are of the first conductivity type.

19. The semiconductor device of claim 14, wherein the third doped region has a second sidewall that is non-linear such that a first portion of the second sidewall is separated from a second portion of the second sidewall by a second portion of the semiconductor body.

20. The semiconductor device of claim 14, wherein:
the semiconductor body has dopants of a first conductivity type; and
dopants of the third doped region are of a second conductivity type different than the first conductivity type.
